(19) United States
(12) Patent Application Publication
(10) Pub. No.: US 2025/0344444 A1
(43) Pub. Date: Nov. 6, 2025

(54) BACKSIDE DIELECTRIC PLUG

(71) Applicant: International Business Machines Corporation, Armonk, NY (US)

(72) Inventors: Chen Zhang, Santa Clara, CA (US); Ruilong Xie, Niskayuna, NY (US); Debarghya Sarkar, Latham, NY (US); Huimei Zhou, Albany, NY (US)

(21) Appl. No.: 18/652,294

(22) Filed: May 1, 2024

(51) Int. Cl. H01L 29/417; H01L 23/528; H01L 29/06; H01L 29/40; H01L 29/423; H01L 29/66; H01L 29/775

(52) U.S. Cl. CPC H10D 30/6729; H01L 23/5286; H10D 30/014; H10D 30/43; H10D 30/6735; H10D 62/121; H10D 64/01

(57) ABSTRACT

A semiconductor integrated circuit (IC) device includes a first source/drain region connected to a second source/drain region by a plurality of active channels, a backside contact that is directly coupled to the first source/drain region, a frontside contact that is directly coupled to the second source/drain region, and a backside dielectric plug that is directly coupled to the second source/drain region and that is directly coupled to the backside contact. In examples, every backside contact placeholder that is associated with a source/drain region that is connected to a frontside contact is removed and replaced by a respective backside dielectric plug. Relative to the backside contact placeholder, the replacement backside dielectric plug may reduce gate-drain Miller capacitance, source/drain capacitance, and may reduce leakage current between source and drain through substrate residue that may reside due to flawed substrate removal during backside processing.

### BACKGROUND

Some modern semiconductor integrated circuit (IC) devices utilize a direct backside contact (DBC) scheme. Typically, in this scheme, a backside contact placeholder is epitaxially grown prior to epitaxially growing a source/drain region thereupon. In order to more precisely control the epitaxial growth of the backside contact placeholders, typically, a respective backside contact placeholder is placed everywhere, or in each source/drain region canyon. Because there are some source/drain regions that do not utilize a backside contact, there are typically locations where the respective backside contact placeholders are retained.

### SUMMARY

In an embodiment of the disclosure, a semiconductor integrated circuit (IC) device is presented. The semiconductor IC device includes a first source/drain region connected to a second source/drain region by a plurality of active channels. The semiconductor IC device further includes a backside contact that is directly coupled to the first source/drain region and a frontside contact that is directly coupled to the second source/drain region. The semiconductor IC device further includes a backside dielectric plug that is directly coupled to the second source/drain region and that is directly coupled to the backside contact.

In another embodiment of the disclosure, another semiconductor integrated circuit (IC) device is presented. The semiconductor IC device includes a totality of source/drain regions in the semiconductor IC device, the totality of source/drain regions consisting of first source/drain regions and second source/drain regions. The first source/drain regions are each directly connected to a respective backside contact and the second source/drain regions are each directly coupled to a respective frontside contact and are each directly coupled to a backside dielectric plug.

In another embodiment of the disclosure, a semiconductor integrated circuit (IC) device fabrication method is present. The method includes forming a backside dielectric plug opening within a backside interlayer dielectric that exposes a first backside contact placeholder. The method further includes exposing a first source/drain region by removing the first backside contact placeholder. The method further includes forming a backside dielectric plug within the backside dielectric plug opening against the first source/drain region. The method further includes, after forming the backside dielectric plug, forming a backside contact opening within the backside interlayer dielectric that exposes a second backside contact placeholder and that exposes a portion of the backside dielectric plug. The method further includes exposing a second source/drain region by removing the second backside contact placeholder. The method further includes forming a backside contact within the backside contact opening against the second source/drain region and against the portion of the backside dielectric plug.

The above summary is not intended to describe each illustrated embodiment or every implementation or example of the present disclosure.

### BRIEF DESCRIPTION OF THE DRAWINGS

The drawings included in the disclosure are incorporated into, and form part of, the specification. They illustrate embodiments of the present disclosure and, along with the description, explain the principles of the disclosure. The drawings are only illustrative of certain embodiments and do not limit the disclosure.

FIG. 1 depicts a cross-section view of an illustrative semiconductor IC device that includes a backside dielectric plug, according to one or more embodiments of the disclosure.

FIG. 2A depicts a partial structure top-down view of an illustrative semiconductor IC device that is formed to include a backside dielectric plug, according to one or more embodiments of the disclosure.

FIG. 2B through FIG. 21 depict various fabrication structure cross-section views of an illustrative semiconductor IC device that is formed to include a backside dielectric plug, according to one or more embodiments of the disclosure.

FIG. 22 depicts a method of fabricating a semiconductor IC device with a backside dielectric plug, according to one or more embodiments of the disclosure.

FIG. 23 depicts a cross-section view of an illustrative backside dielectric plug, according to one or more embodiments of the disclosure.

### DETAILED DESCRIPTION

The embodiments of the present disclosure relate to fabrication methods and resulting structures for semiconductor IC devices. More specifically, the present disclosure relates to fabrication methods and resulting semiconductor integrated circuit (IC) devices that include a backside dielectric plug that is formed to adequately electrically isolate, or disconnect, a portion of a channel (e.g., one or more nanolayer channels) from either its previously associated source region or drain region. This scheme may be utilized to modify transistors within a first region, such as a low power device region of a semiconductor IC device relative to transistors within a second region, such as a high performance region of the same semiconductor IC device while largely utilizing the same fabrication stages to form the various transistors.

A transistor is a type of microdevice that may be fabricated in semiconductor IC device front-end-of-line (FEOL) fabrication operations. Conventional transistors, or the like, incorporate planar field effect transistors (FETs) in which current flows through a semiconducting channel between a source and a drain, in response to a voltage applied to the gate. The semiconductor industry strives to obey Moore's law, which holds that each successive generation of integrated circuit devices shrinks to half its size and operates twice as fast. As device dimensions have shrunk, however, conventional silicon device geometries and materials have had trouble maintaining switching speeds without incurring failures such as, for example, leaking current from the device into the semiconductor substrate. Several new technologies emerged that allowed chip designers to continue shrinking transistor sizes. A FET generally is a transistor in which output current, i.e., source-drain current, is controlled by a voltage applied to an associated gate. A FET typically has three terminals, i.e., a gate structure, a source region, and a drain region. A gate structure is a structure used to control output current (i.e., flow of carriers in the channel) of a semiconducting device through electrical or magnetic fields. A channel is the region of the FET underlying the gate structure and between the source and drain of the semiconductor IC device that becomes conductive when the semiconductor device is turned on. The source is a doped region in the semiconductor IC device, in which majority carriers are flowing into the channel. A drain is a doped region in the semiconductor IC device located at the end of the channel, in which carriers are flowing out of the transistor through the drain.

One technology change modified the structure of the FET from a planar device to a three-dimensional device in which the semiconducting channel was replaced by a fin that extends out from the plane of the substrate. In such a device, commonly referred to as a FinFET, the control gate wraps around three sides of the fin to influence current flow from three surfaces instead of one. The improved control achieved with a 3D design results in faster switching performance and reduced current leakage. Building taller devices has also permitted increasing the device density within the same footprint that had previously been occupied by a planar FET.

The FinFET concept was further extended by developing a gate all-around FET, or GAA FET, in which the gate fully wraps around one or more channels for maximum control of the current flow therein. In the GAA FET, the channels can take the form of nanolayers, nanolayers, or the like, that are isolated from the substrate. In the GAA FET, channel surfaces are in respective contact with the source and drain and other respective channel surfaces are in contact with and surrounded by the gate.

The flowcharts and cross-sectional diagrams in the drawings illustrate a method of fabricating a semiconductor IC device, such as a processor, filed programmable gate array (FPGA), memory module, or the like. In some alternative implementations, the fabrication steps may occur in a different order than that which is noted in the drawings, and certain additional fabrication steps may be implemented between the steps noted in the drawings. Moreover, any of the layered structures depicted in the drawings may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” if the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the depicted structure(s) as oriented. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements.

The terms “about,” “substantially,” “approximately,” and variations thereof, are intended to include the degree of error associated with measurement of the particular quantity based upon the equipment available at the time of filing the application. For example, substantial coplanarity between various materials can include an appropriate manufacturing tolerance of +8%, +5%, +2%, or the like, difference between the coplanar materials.

As used herein, the term “coplanar” refers to two surfaces that lie in a common plane. In other words, two surfaces are coplanar if there exists a geometric plane that contains all the points of both of the surfaces. Accordingly, two surfaces may be referred to as substantially coplanar despite deviations from coplanarity, so long as those deviations do not impact the desired result of the coplanarity.

As used herein, the terms “selective” or “selectively” in reference to a material removal or etch process denote that the rate of material removal for a first material is greater than the rate of removal for at least another material of the structure to which the material removal process is applied. For example, in certain embodiments, a selective etch may include an etch chemistry that removes a first material selectively to a second material by a ratio of 2:1 or greater, e.g., 5:1, 10:1 or 20:1.

For the sake of brevity, conventional techniques related to semiconductor IC device fabrication may or may not be described in detail and/or depicted herein. Moreover, the various tasks and process steps described herein can be incorporated into a more comprehensive procedure or process having additional steps or functionality not described and/or not depicted in detail herein. Various steps in the manufacture of semiconductor devices are well known and so, in the interest of brevity, many conventional steps will only be mentioned briefly herein, will be omitted entirely without providing the well-known process details, and/or will not be depicted.

In general, the various processes used to form a semiconductor IC device that may be packaged into an IC package fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photoresist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, a metal-oxide-semiconductor field-effect transistor (MOSFET) may be used for amplifying or switching electronic signals. The MOSFET has a source electrode, a drain electrode, and a metal oxide gate electrode. The metal gate portion of the metal oxide gate electrode is electrically insulated from the main semiconductor n-channel or p-channel by a thin layer of insulating material, for example, silicon dioxide or glass, which makes the input resistance of the MOSFET relatively high. The gate voltage controls whether the current path from the source to the drain is an open circuit (“off”) or a resistive path (“on”). N-type field effect transistors (nFET) and p-type field effect transistors (pFET) are two types of complementary MOSFETs. The nFET includes n-doped source and drain regions and uses electrons as the charge carrier. The pFET includes p-doped source and drain regions and uses holes as the charge carrier. Complementary metal oxide semiconductor (CMOS) is a technology that uses complementary and symmetrical pairs of p-type and n-type MOSFETs to implement logic functions. As mentioned above, hole mobility on the pFET may have an impact on overall device performance.

The wafer footprint of a FET is related to the electrical conductivity of the channel material. If the channel material has a relatively high conductivity, the FET can be made with a correspondingly smaller wafer footprint. A method of increasing channel conductivity and decreasing FET size is to form the channel as a nanostructure, such as a nano wire, nano ribbon, nanolayer, nanolayer, or the like, hereinafter referred to as a nanolayer. For example, a GAA FET provides a relatively small FET footprint by forming the channel region as a series of vertically stacked nanolayers. In a GAA configuration, a GAA FET includes a source region, a drain region and vertically stacked nanolayer channels between the source and drain regions. These devices typically include one or more suspended nanolayers that serve as the channel. A gate surrounds the stacked nanolayers and regulates electron flow through the nanolayers between the source and drain regions. GAA FETs may be fabricated by forming alternating layers of active nanolayers and sacrificial nanolayers. The sacrificial nanolayers are released from the active nanolayers before the FET device is finalized. For n-type FETs, the active nanolayers are typically silicon (Si) and the sacrificial nanolayers are typically silicon germanium (SiGe). For p-type FETs, the active nanolayers can be SiGe and the sacrificial nanolayers can be Si. In some implementations, the active nanolayers of a p-type FET can be SiGe or Si, and the sacrificial nanolayers can be Si or SiGe. Forming the nanolayers from alternating layers of active nanolayers formed from a first type of semiconductor material (e.g., Si for n-type FETs, and SiGe for p-type FETs) and sacrificial nanolayers formed from a second type of semiconductor material (e.g., SiGe for n-type FETs, and Si for p-type FETs) may provide for improved channel electrostatics control.

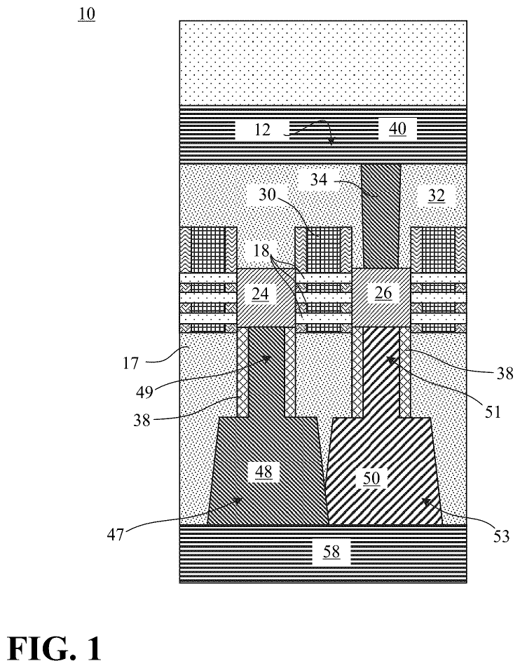

Referring now to the figures, FIG. 1 depicts a cross-sectional view of an illustrative semiconductor integrated circuit (IC) device 10. The semiconductor IC device 10 includes a first source/drain region 24 connected to a second source/drain region 26 by a plurality of active channels 18. The semiconductor IC device 10 further includes a backside contact 48 that is directly coupled to the first source/drain region 24. The semiconductor IC device 10 further includes a frontside contact 34 that is directly coupled to the second source/drain region 26. The semiconductor IC device 10 further includes a backside dielectric plug 50 that is directly coupled to the second source/drain region 26 and that is directly coupled to the backside contact 48. The first source/drain region 24, the second source/drain region 26, the plurality of active channels 18, and a gate 30 may form a transistor 12.

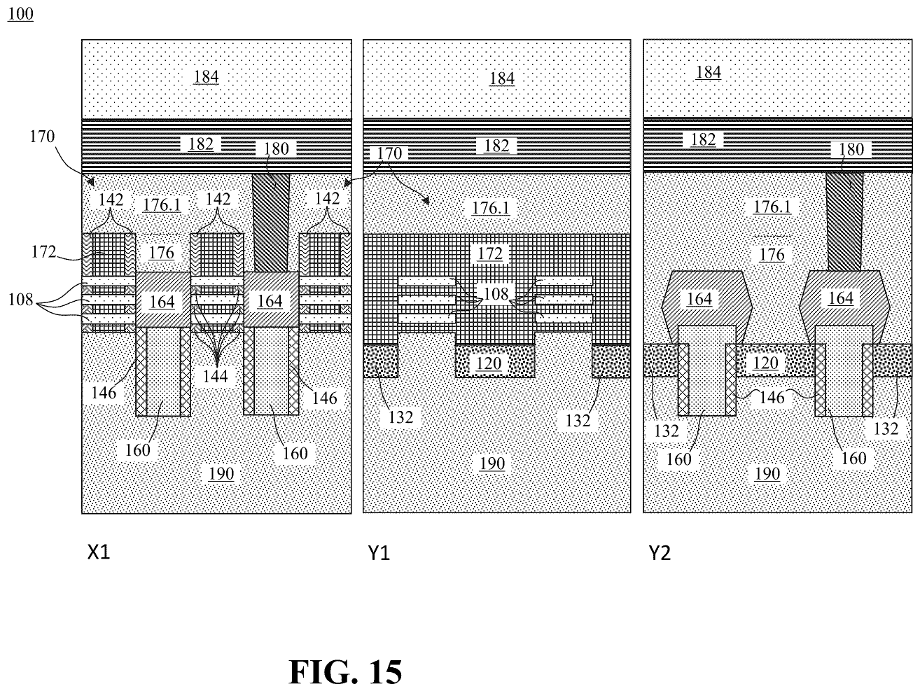

The backside dielectric plug 50 may replace an associated backside contact placeholder, such as backside contact placeholder 160 depicted in FIG. 15, that would otherwise remain underneath the second source/drain region 26 within the semiconductor IC device 10. Relative to the backside contact placeholder, the backside dielectric plug 50 may reduce the Miller capacitance between a gate 30 and the first source/drain region 24 or between the gate 30 and the second source/drain region 26. Further, relative to the backside contact placeholder, the backside dielectric plug 50 may reduce the capacitance between the first source/drain region 24 and the second source/drain region 26. Even further, relative to the backside contact placeholder, the backside dielectric plug 50 may reduce leakage current between the first source/drain region 24 and the second source/drain region 26 through substrate residue (not shown) that may reside due to flawed substrate removal during backside processing.

In an example, a portion of a sidewall of the backside dielectric plug 50 is directly coupled to a portion of a sidewall of the backside contact 48. This may be the result of the backside dielectric plug 50 being formed prior to the backside contact 48 being formed. During the formation of the backside contact 48, an associated backside contact opening may cut or otherwise remove or expose a portion of the backside dielectric plug 50. Therefore, when the backside contact 48 is formed within the backside contact opening, the backside contact 48 may be formed directly coupled to the exposed portion of the backside dielectric plug 50.

In an example, the semiconductor IC device 10 further includes a frontside back end of line (BEOL) network 40 that is connected to the frontside contact 34. The frontside BEOL network 40 may include a frontside wiring network, in which one or more wires may be electrically connected to the frontside contact 34 to control the potential applied to the second source/drain region 26. The frontside contact 34 may be formed within a frontside ILD 32.

In an example, the semiconductor IC device 10 further includes a backside BEOL network 58 that is connected to the backside contact 48 and to the backside dielectric plug 50. The backside BEOL network 58 may include a backside wiring network, in which one or more wires may be electrically connected to the backside contact 48 to control the potential applied to the first source/drain region 24.

In an example, the semiconductor IC device 10 further includes the gate 30 that is connected to the plurality of active channels. The gate 30 may further be electrically connected to a wire within a BEOL network so as to control the potential applied to gate 30 which may turn the associated transistor 12 on or off. Further, the backside dielectric plug 50 may reduce the Miller capacitance between the gate 30 and the second source/drain region 26.

In an example, the plurality of active channels 18 are vertically stacked. For example, the active channels 18 may be GAA nanosheet channels and the gate 30 may wrap around and contact each side (e.g., top, bottom, front, and rear) of each of the active channels 18 and may provide for increased electrostatic control.

In an example, the semiconductor IC device 10 further includes a backside interlayer dielectric (ILD) 17 directly coupled to the backside contact 48 and directly coupled to the backside dielectric plug 50. The backside ILD 17 may provide for the material(s) for the backside contact 48 and the backside dielectric plug 50 to be formed therein.

In an example, the backside dielectric plug 50 includes a gabled sidewall comprising a first sidewall surface directly coupled to the backside ILD 17 and a second sidewall surface that meets the first sidewall surface and that is directly coupled to backside contact 48. This may be the result of the backside dielectric plug 50 being formed prior to the backside contact 48 being formed. During the formation of the backside contact 48, an associated backside contact opening may cut or otherwise remove or expose a portion of the backside dielectric plug 50, thereby forming the second sidewall surface of the gabled sidewall. Therefore, when the backside contact 48 is formed within the backside contact opening, the backside contact 48 may be formed directly coupled to the second sidewall surface of the gabled sidewall.

In examples, the backside dielectric plug is composed of a first dielectric material and the backside ILD is composed of a second dielectric material that is different from the first dielectric material. This may allow for the backside dielectric plug to have a relatively higher dielectric coefficient relative to the backside ILD 17, e.g., to better electrically isolate different backside contacts 48, or the like.

In examples, the backside dielectric plug 50 comprises an upper region 51 with a first horizontal dimension and a lower region 53 with a second horizontal dimension greater than the first horizontal dimension. The upper region 51 may be formed by the removal of an associated backside contact placeholder and the first horizontal dimension may be so constrained. The lower region 53 may be relatively wider to allow for the backside contact 48 to be directly coupled to the lower region 53 of the backside dielectric plug 50.

In examples, the backside contact 48 comprises an upper region 49 with a first horizontal dimension and a lower region 47 with a second horizontal dimension greater than the first horizontal dimension. The upper region 49 may be formed by the removal of an associated backside contact placeholder and the first horizontal dimension may be so constrained. The lower region 47 may be relatively wider to allow for the backside dielectric plug 50 to be directly coupled to the lower region 47 of the backside contact 48.

In an example, the backside contact 48 comprises a linear sidewall that is directly coupled to the backside ILD 17 and that is directly coupled to backside dielectric plug 50. This may result from the backside contact 48 being formed after the backside dielectric plug to provide for a liner sidewall, as opposed to the gabled sidewall of the first formed backside dielectric plug 50.

In an example, the semiconductor IC device 10 further includes a vertical liner 38 that is directly coupled to the upper region of the backside dielectric plug 50 and that is directly coupled to the backside ILD 17. The vertical liner 38 may provide for additional electrical isolation between the first source/drain region 24 and the second source/drain region 26 and/or the backside contact 48.

In another embodiment, a semiconductor IC device is disclosed. The semiconductor IC device includes a totality of source/drain regions in the semiconductor IC device. The totality of source/drain regions consists of first source/drain regions 24 and second source/drain regions 26. The first source/drain regions 24 are each directly connected to a respective backside contact 48 and the second source/drain regions 26 are each directly coupled to a respective frontside contact 34 and are each directly coupled to a backside dielectric plug 50. Therefore, the semiconductor IC device 10 is formed utilizing a backside contact placeholder everywhere scheme. In locations where the first source/drain regions 24 are connected to a backside BEOL network 58, a backside contact 48 is formed in place of the removed respective backside contact placeholder. In locations where the second source/drain regions 26 are connected to a frontside BEOL network 40, a backside contact plug 50 is formed in place of the removed respective backside contact placeholder.

Relative to the backside contact placeholder, the backside dielectric plug 50 may reduce the Miller capacitance between a gate 30 and the first source/drain region 24 or between the gate 30 and the second source/drain region 26. Further, relative to the backside contact placeholder, the backside dielectric plug 50 may reduce the capacitance between the first source/drain region 24 and the second source/drain region 26. Even further, relative to the backside contact placeholder, the backside dielectric plug 50 may reduce leakage current between the first source/drain region 24 and the second source/drain region 26 through substrate residue (not shown) that may reside due to flawed substrate removal during backside processing.

In an example, each backside dielectric plug is directly coupled to one or more of the backside contacts. This may be the result of the backside dielectric plug 50 being formed prior to the backside contact(s) 48 being formed. During the formation of the backside contact(s) 48, an associated backside contact opening may cut or otherwise remove or expose a portion of the backside dielectric plug 50. Therefore, when the backside contact 48 is formed within the backside contact opening, the backside contact 48 may be formed directly coupled to the exposed portion(s) of the backside dielectric plug 50.

In an example, the semiconductor IC device further includes the frontside BEOL network 40 that is connected to each of the respective frontside contacts 34. The frontside BEOL network 40 may include a frontside wiring network, in which one or more wires may be electrically connected to a respective frontside contact 34 to control the potential applied to the associated second source/drain region 26.

In an example, the semiconductor IC device further includes the backside BEOL network 58 that is connected to each of the respective backside contacts 48 and that is connected to each of the respective backside dielectric plugs 50. The backside BEOL network 58 may include a backside wiring network, in which one or more wires may be electrically connected to a respective backside contact 48 to control the potential applied to the associated first source/drain region 24.

In an example, the semiconductor IC device further includes backside ILD 17 directly coupled to each of the respective backside contacts 48 and directly coupled to each of the respective backside dielectric plugs 50. The backside ILD 17 may provide for the material(s) for the backside contacts 48 and the backside dielectric plugs 50 to be formed therein.

In an example, each of the respective backside dielectric plugs 50 include a gabled sidewall that has a first sidewall surface directly coupled to the backside ILD 17 and a second sidewall surface that meets the first sidewall surface and that is directly coupled to a respective backside contact 48. The term “gabled sidewall”, or the like, is defined herein as a integrated sidewall or side surface that has two surfaces or planes joined together at an angle that is less than one hundred eighty degrees. The gabled sidewall may be the result of the backside dielectric plugs 50 being formed prior to the backside contacts 48 being formed. During the formation of the backside contacts 48, and associated backside contact opening may cut or otherwise remove or expose a portion of a respective backside dielectric plug 50, thereby forming the second sidewall surface of the gabled sidewall. Therefore, when the respective backside contact 48 is formed within the associated backside contact opening, the backside contact 48 may be formed directly coupled to the second sidewall surface of the gabled sidewall.

In an example, each of the respective backside dielectric plugs 50 are composed of a first dielectric material and the backside ILD 17 is composed of a second dielectric material that is different from the first dielectric material. This may allow for the backside dielectric plug 50 to have a relatively higher dielectric coefficient relative to the backside ILD 17, e.g., to better electrically isolate different backside contacts 48, or the like.

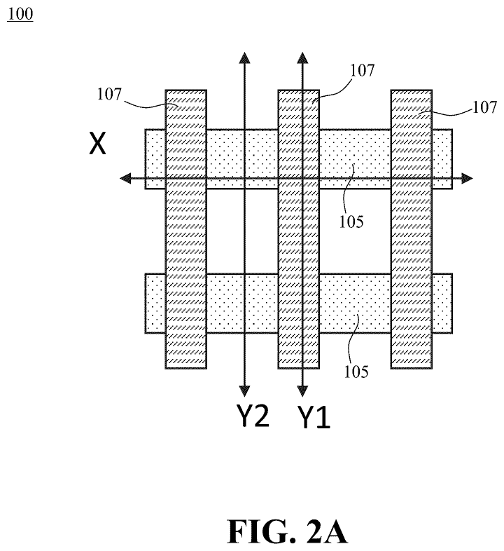

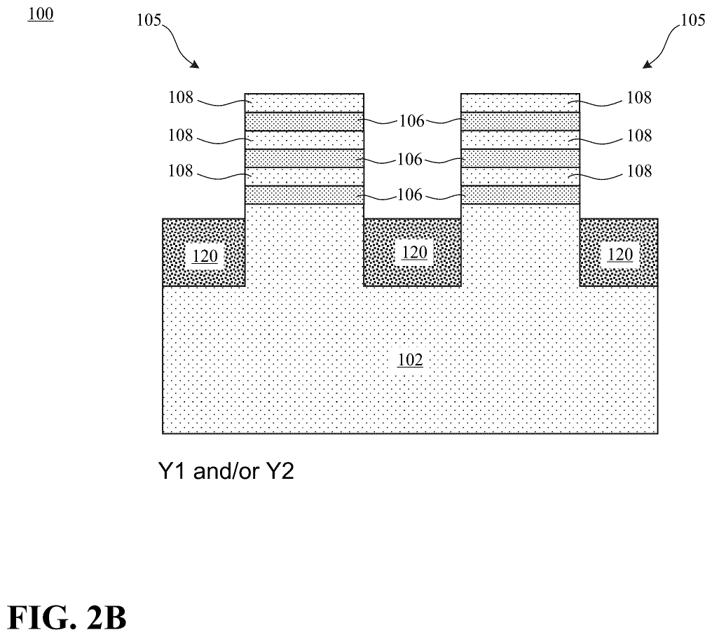

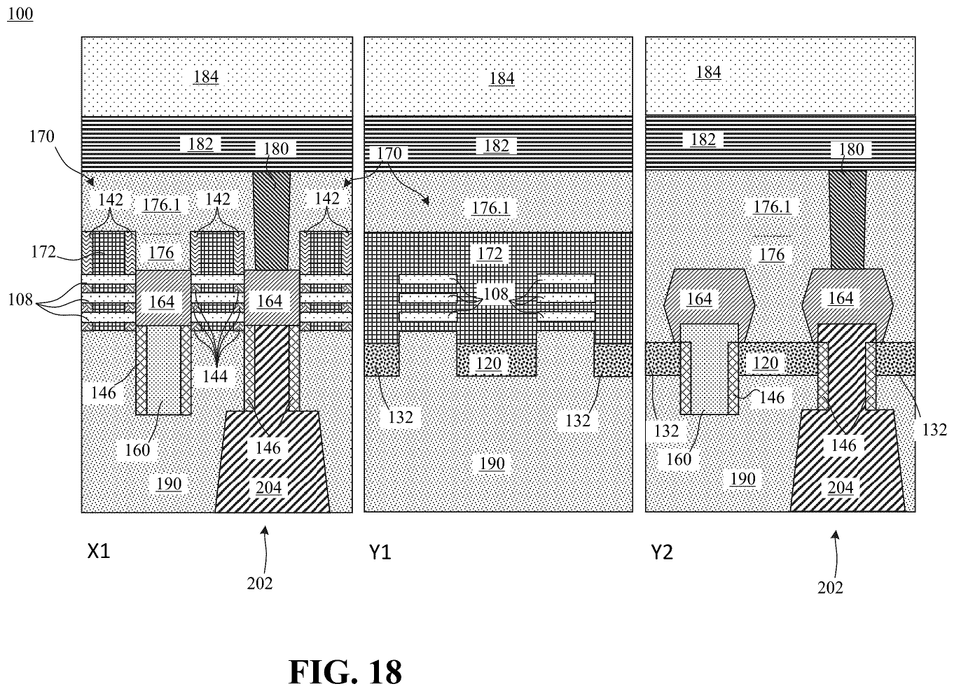

FIG. 2A depicts a partial structural top-down view of an illustrative semiconductor IC device 100 that is formed to include a backside dielectric plug 204 (depicted in FIG. 18). The illustrated semiconductor IC device 100 depicts multiple nanolayer rows 105 and multiple gate structures 107 (e.g., sacrificial gate structures or replacement gate structures depending upon a reference stage semiconductor IC device 100 of fabrication). For clarity, at the stage of semiconductor IC device 100 fabrication when nanolayer rows 105 are present, the gate structures 107 may be sacrificial gate structures and when associated active areas are present, the gate structures 107 may be replacement gate structures. The nanolayer rows 105 may define respective active areas of the semiconductor IC device 100.

FIG. 2A also depicts a cross-sectional plane X, which is a vertical plane across various gate structures 107 through a nanolayer row 105, cross-sectional plane Y1, which is a vertical plane through a gate structure 107 across nanolayer rows 105, and a cross-sectional plane Y2, which is a vertical plane across nanolayer rows 105. The cross-sectional planes X, Y1, and Y2 establish the planes of the cross-sectional views of the semiconductor IC device 100 depicted in FIG. 2B through FIG. 21.

FIG. 2B depicts a cross-sectional initial fabrication view of the semiconductor IC device 100 that is formed to include a backside dielectric plug 204. At this initial fabrication stage, the semiconductor IC device 100 may include a substrate structure 102, shallow trench isolation (STI) regions 120, and nanolayer rows 105.

For clarity, the fabrication of the semiconductor IC device 100 at the present stage may utilize processes that may now be known or that may be developed in the future. For illustration purposes, a particular fabrication process to form semiconductor IC device 100 at the present stage is presented below. This illustrative methodology may be one of many that may achieve or result in the initial semiconductor IC device 100, as depicted. When components referenced in the illustrative methodology below are depicted in FIG. 2B, such associated component numeral is expressly utilized. Otherwise, when components are referenced in the illustrative methodology that are not depicted in FIG. 2B, a component numeral is not denoted.

The illustrative semiconductor IC device 100 may be formed by initially providing or forming a substrate structure 102. The substrate structure 102 may be a bulk-semiconductor substrate. In one example, the bulk-semiconductor substrate may be a silicon-containing material. In another implementation, the substrate structure 102 includes an upper substrate, a lower substrate, and an etch stop layer between the upper substrate and the lower substrate. The upper substrate and the lower substrate may be comprised of any suitable semiconductor material(s), and the etch stop layer may be a dielectric material with etch selectivity to one or both upper substrate and/or the lower substrate. In one example, the etch stop layer may be an oxide and the substrate structure may be referred to as a buried oxide (BOX) substrate. In another example, the lower substrate may be composed of Si. The etch stop layer may be composed of Silicon Germanium (SiGe) and may be epitaxially grown from the top surface of lower substrate and the upper substrate may be composed of Si and may be epitaxially grown from the top surface of etch stop layer.

Next, the illustrative semiconductor IC device 100 may be formed by forming nanolayers over the substrate structure by forming a series of alternating sacrificial nanolayers 106 and active nanolayers 108. In certain examples, the bottommost sacrificial nanolayer 106 is initially formed directly on an upper surface of the substrate structure 102. In other examples, certain layer(s) may be formed between the upper surface of the substrate structure 102 and the bottommost sacrificial nanolayer 106.

The nanolayers may be formed by fabricating the alternating series of sacrificial nanolayers 106, such as SiGe sacrificial nanolayers, and active nanolayers 108, such as Si nanolayers. The sacrificial nanolayers 106 can have Ge percentages ranging from 20% to 45%. In an implementation, the alternating active sacrificial nanolayer 106 and active nanolayer 108 may be formed by epitaxially growing each layer until the desired number and desired thicknesses of the layers are achieved. Any number of alternating nanolayers can be provided. Epitaxial materials can be grown from gaseous or liquid precursors. For example, epitaxial materials can be grown using vapor-phase epitaxy (VPE), molecular-beam epitaxy (MBE), liquid-phase epitaxy (LPE), or other suitable processes.

The terms “epitaxial growth and/or deposition” and “epitaxially formed and/or grown” mean the growth of a semiconductor material (crystalline material) on a deposition surface of another semiconductor material (crystalline material), in which the semiconductor material being grown (crystalline overlayer) has substantially the same crystalline characteristics as the semiconductor material of the deposition surface (seed material). In an epitaxial deposition process, the chemical reactants provided by the source gases are controlled and the system parameters are set so that the depositing atoms arrive at the deposition surface of the semiconductor substrate with sufficient energy to move about on the surface such that the depositing atoms orient themselves to the crystal arrangement of the atoms of the deposition surface. Therefore, an epitaxially grown semiconductor material has substantially the same crystalline characteristics as the deposition surface on which the epitaxially grown material is formed. For example, an epitaxially grown semiconductor material deposited on a (100) orientated crystalline surface will take on a (100) orientation. In some embodiments, epitaxial growth and/or deposition processes are selective to forming on semiconductor surfaces, and generally do not deposit material on exposed surfaces, such as silicon dioxide or silicon nitride surfaces.

Although it is specifically contemplated that the sacrificial nanolayers 106 can be formed from SiGe and that the active nanolayers 108 can be formed from Si, it should be understood that any appropriate materials can be used instead, as long as the semiconductor materials have etch selectivity with respect to one or more of the others, as is consistent with the description of the fabrication stages herein. Although it is specifically contemplated that the sacrificial nanolayers 106 and the active nanolayers 108 are formed by epitaxial growth, such nanolayers can be formed by any appropriate deposition mechanism.

Further, in the depicted fabrication stages, the nanolayers may be patterned into nanolayer rows 105, and STI regions 120 may be formed within the substrate structure 102 adjacent to the nanolayer rows 105.

The one or more nanolayer rows 105 may be formed by lithography and etching techniques. Following the nanolayer row 105 patterning process, the one or more nanolayer rows 105 are formed. The removal of undesired portion(s) of the nanolayers may further remove undesired portions of substrate structure 102 that are adjacent to respective footprints of nanolayer rows 105 to form STI region openings. A STI region 120 may be formed upon and/or within the substrate structure 102 within respective STI region openings. The STI regions 120 may be formed by depositing electrical dielectric material(s) within respective STI region opening(s). A top surface of the one or more STI regions 120 may be initially coplanar with or below a top surface of the substrate structure 102.

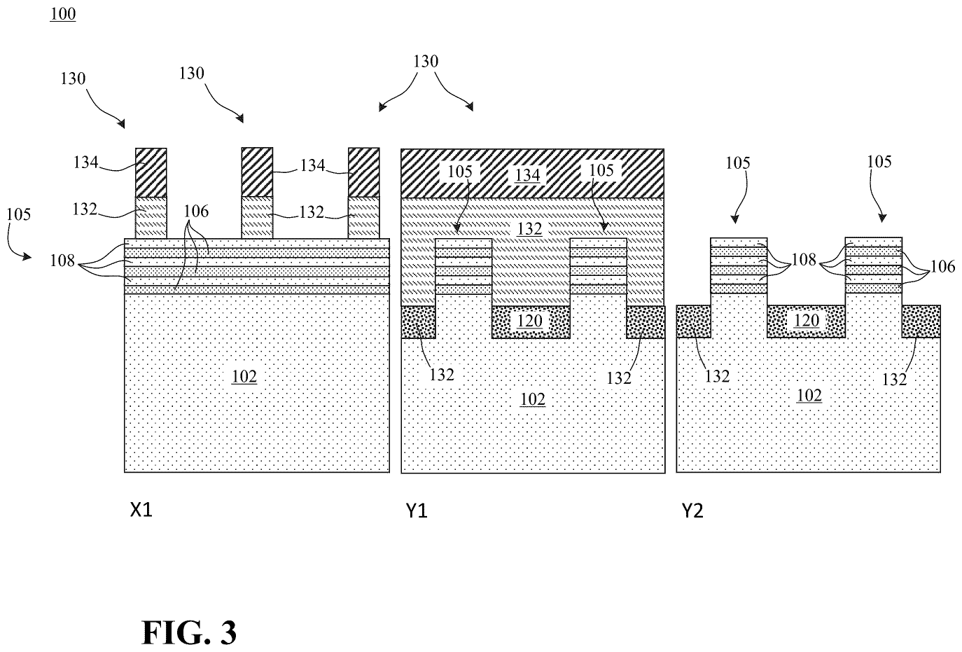

FIG. 3 depicts cross-sectional views of the semiconductor IC device 100 after fabrication operations, in accordance with embodiments of the present disclosure. In the depicted fabrication stages, sacrificial gate structures 130 may be formed.

The sacrificial gate structures 130 may include a sacrificial gate liner (not shown), a sacrificial gate 132, and a sacrificial gate cap 134. The sacrificial gate structures 130 may be formed by initially depositing a sacrificial gate liner (e.g., a dielectric, oxide, or the like) upon the one or more STI regions 120 and upon and around the one or more nanolayer rows 105. The sacrificial gate structures 130 may further be formed by subsequently depositing a sacrificial gate layer (e.g., amorphous silicon, or the like) upon the sacrificial gate liner layer. The thickness of the sacrificial gate layer may be such that the top surface of the sacrificial gate layer is above the top surface of the one or more nanolayer rows 105. The sacrificial gate structures 130 may further be formed by forming a gate cap layer upon the sacrificial gate layer. The gate cap layer may be formed by depositing a mask material, such as a hard mask material, such as silicon nitride, silicon oxide, combinations thereof, or the like, upon the sacrificial gate layer. The gate cap layer may be composed of one or more layers of masking materials to protect the sacrificial gate layer and/or other underlying materials during subsequent processing of semiconductor IC device 100.

The one or more sacrificial gate structures 130 may further be formed by patterning the gate cap layer, sacrificial gate layer, and sacrificial gate liner by, for example, using lithography and etch processes to remove undesired portions and retain desired portion(s), respectively. The retained desired portion(s) of the gate cap layer, sacrificial gate layer, and sacrificial gate liner may form the sacrificial gate liner (not shown), the sacrificial gate 132, and the sacrificial gate cap 134, respectively, of each of the one or more sacrificial gate structures 130.

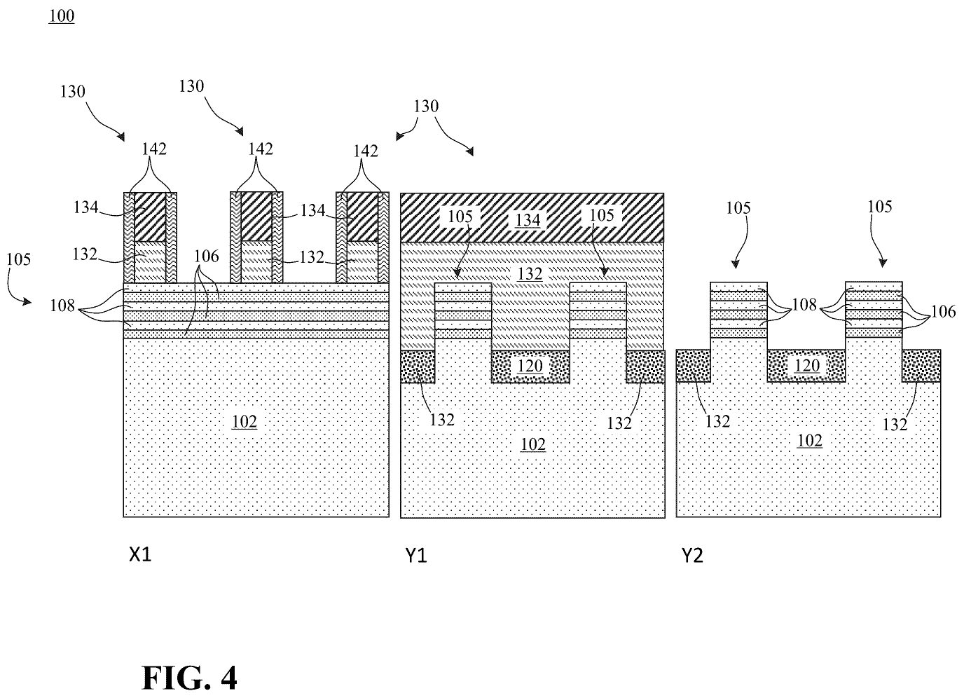

FIG. 4 depicts cross-sectional views of the semiconductor IC device 100 after fabrication operations, in accordance with embodiments of the present disclosure. In the depicted fabrication stages, gate spacers 142 may be formed.

The gate spacer(s) 142 may be formed by a conformal deposition of a dielectric material, such as silicon nitride, SiBCN, SINC, SiN, SiCO, SiNOC, or a combination thereof, or the like, upon STI regions 120, upon around the one or more sacrificial gate structures 130, and upon and around the one or more nanolayer rows 105. Subsequently, undesired portions of dielectric material may be removed while desired portions the dielectric material may be retained to thereby form the gate spacer(s) 142 located generally upon the sidewalls of the sacrificial gate structures 130.

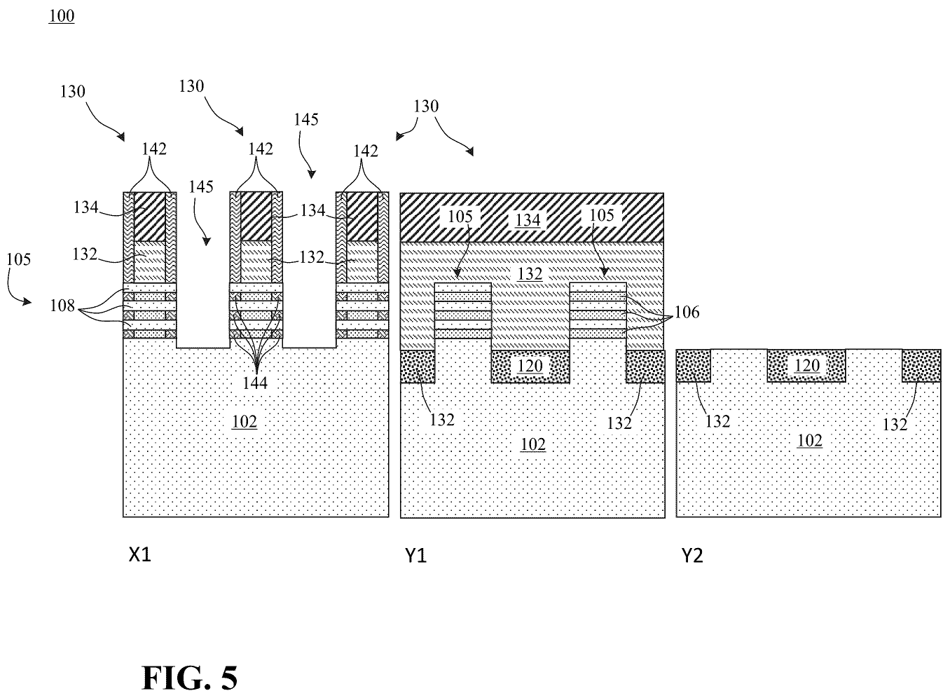

FIG. 5 depicts cross-sectional views of the semiconductor IC device 100 after fabrication operations, in accordance with embodiments of the present disclosure. In the depicted fabrication stages, source/drain canyons 145 may be formed.

The source/drain canyons 145 may be formed within the nanolayer rows 105 and within the substrate structure 102 between gate spacers 142 of neighboring sacrificial gate structures 130. In other words, a single nanolayer row 105 may be separated, by one or more recesses, into multiple nanolayer stacks each located underneath at a portion of respective sacrificial gate structure 130 and associated gate spacers 142.

The source/drain canyons 145 may be formed between adjacent sacrificial gate structures 130 by removing respective portions of the sacrificial nanolayers 106 and active nanolayers 108 that are between gate spacers 142 of adjacent or neighboring sacrificial gate structures 130. The source/drain canyons 145 may be formed to a depth to stop at the top surface or below the top surface of the substrate structure 102. The undesired portions of sacrificial nanolayers 106, active nanolayers 108, and the like, may be removed by etching or other subtractive removal techniques. As the gate spacers 142 and the sacrificial gate structures 130 may be utilized to protect the underlying portions of sacrificial nanolayers 106, active nanolayers 108, respective sidewalls of the nanolayer stacks may be substantially coplanar and substantially vertical with the outer sidewalls of the gate spacers 142 there above.

As used herein, “substantially vertical” sidewalls deviate from a direction normal to a major surface (e.g., top surface, etc.) of the substrate structure 102 by less than 5°, e.g., 0°, 1°, 2°, 3°, 4°, or 5°, including ranges between any of the foregoing values.

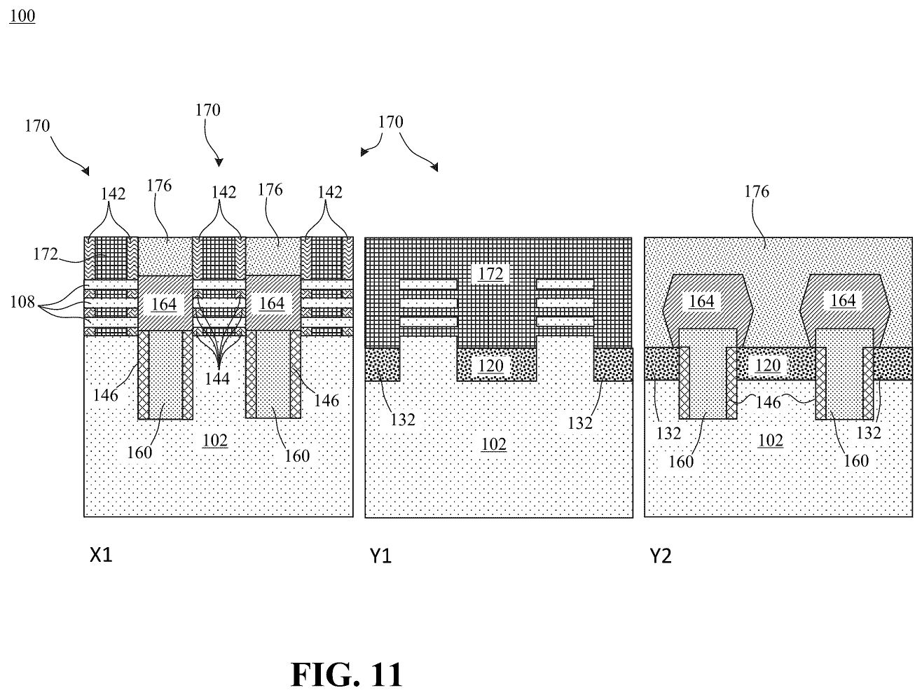

The illustrated semiconductor IC device 100 may be further fabricated by forming horizontal or lateral indents (shown with a respective inner spacer 144 formed therewithin) by laterally or horizontally removing respective portions of sacrificial nanolayers 106 within the nanolayer stacks. The indents may be formed by a reactive ion etch (RIE) process, which can remove portions of the sacrificial nanolayers. The horizontal depth of the indents may be chosen to set a length for a replacement gate structure 170, shown in FIG. 11, that is formed in place of one sacrificial gate structure 130. When the sacrificial nanolayers 106 are composed of SiGe and when active nanolayers 108 are Si, the directional RIE can use a boron-based chemistry or a chlorine-based chemistry, for example, which recesses or removes the exposed end portions of sacrificial nanolayers 106 (e.g., end portions of sacrificial nanolayers generally below spacer 140) selective to the Si active nanolayers 108. In alternative implementations when sacrificial nanolayers 106 are not SiGe and when active nanolayers 108 are not Si, the directional etch of the sacrificial nanolayers 106 may generally be selective to the active nanolayers 108, gate spacers 142, STI regions 120, and/or substrate structure 102.

The illustrated semiconductor IC device 100 may be further fabricated by forming a respective inner spacer 144 within each indent. The one or more inner spacers 144 can be formed by ALD or CVD or any other suitable deposition technique that deposits a dielectric material within the indent(s), thereby forming the inner spacer(s) 144. In some examples, the inner spacer(s) 144 are composed of a low-K dielectric material (a material with a lower dielectric constant relative to SiO₂), SiN, SiO, SiBCN, SiOCN, SiCO, etc. or any other suitable dielectric material. In certain implementations, after the formation of the inner spacer(s) 144, a directional etch process is performed to create substantially vertical sidewalls of the inner spacer(s) 144 that are coplanar with the substantially vertical sidewalls of the active nanolayers 108, of the gate spacers 142, or the like.

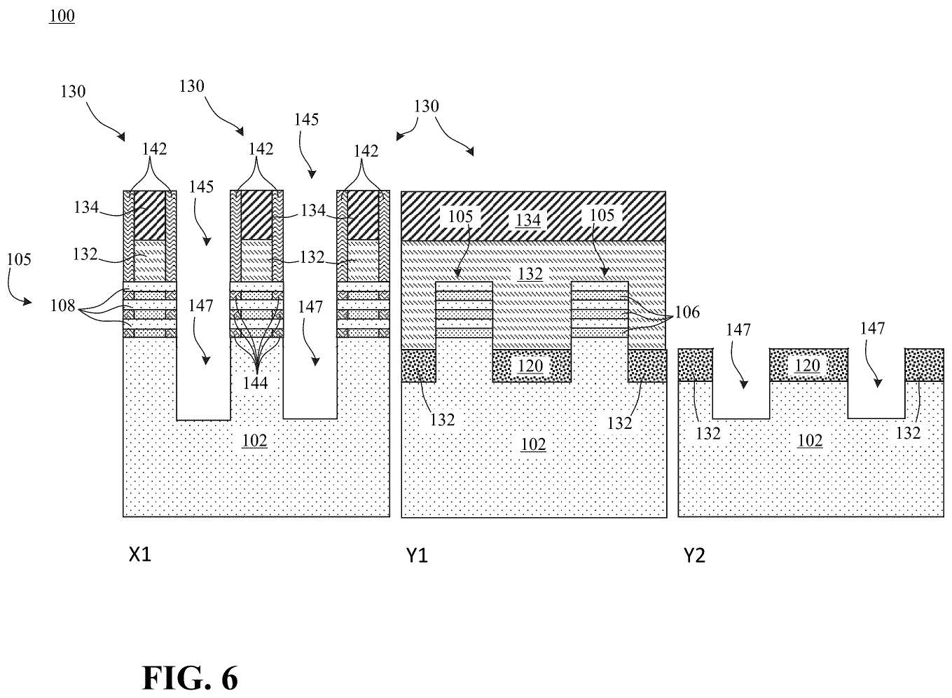

FIG. 6 depicts cross-sectional views of the semiconductor IC device 100 after fabrication operations, in accordance with embodiments of the present disclosure. In the depicted fabrication stages, backside contact placeholder trenches 147 are formed in each source/drain canyon 145.

The backside contact placeholder trenches 147 may be formed by deepening the source/drain canyons 145 within the substrate structure 102 between neighboring sacrificial gate structures 130. The substrate structure 102 may be removed by an etch process that may be controlled so that the well surface of the source/drain canyons 145 stops above the etch stop layer (not shown) of the substrate structure 102. The depth of the etch that forms backside contact placeholder trenches 147 may be chosen to allow for adequate volume of so that a backside contact placeholder may be formed therein. For clarity, a respective backside contact placeholder trench 147 is formed in each location in which a source/drain region is to be formed there above.

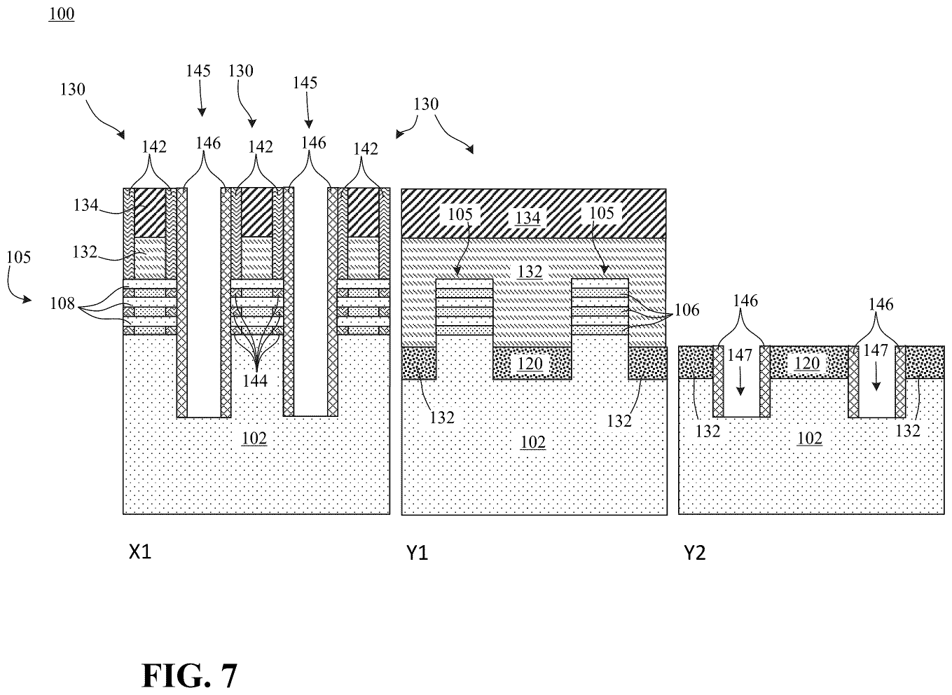

FIG. 7 depicts cross-sectional views of the semiconductor IC device 100 after fabrication operations, in accordance with embodiments of the present disclosure. In the depicted fabrication stages, channel edge liners 146 are formed.

The channel edge liners 146 may be formed by a conformal deposition of a dielectric material, such as silicon oxide, silicon nitride, or a combination thereof, that has etch selectivity to the material of gate spacers 142, inner spacers 144, active nanolayers 108, etc. The dielectric may be deposited as a blanket layer upon the sacrificial gate cap 134, gate spacers 142, active nanolayers 108, inner spacers 144, STI regions 120, and substrate structure 102. Subsequently, undesired horizontal portions of dielectric material may be removed while desired vertical portions the dielectric material may be retained to thereby form the channel edge liners 146 located generally upon the sidewalls of at least the backside contact placeholder trenches 147.

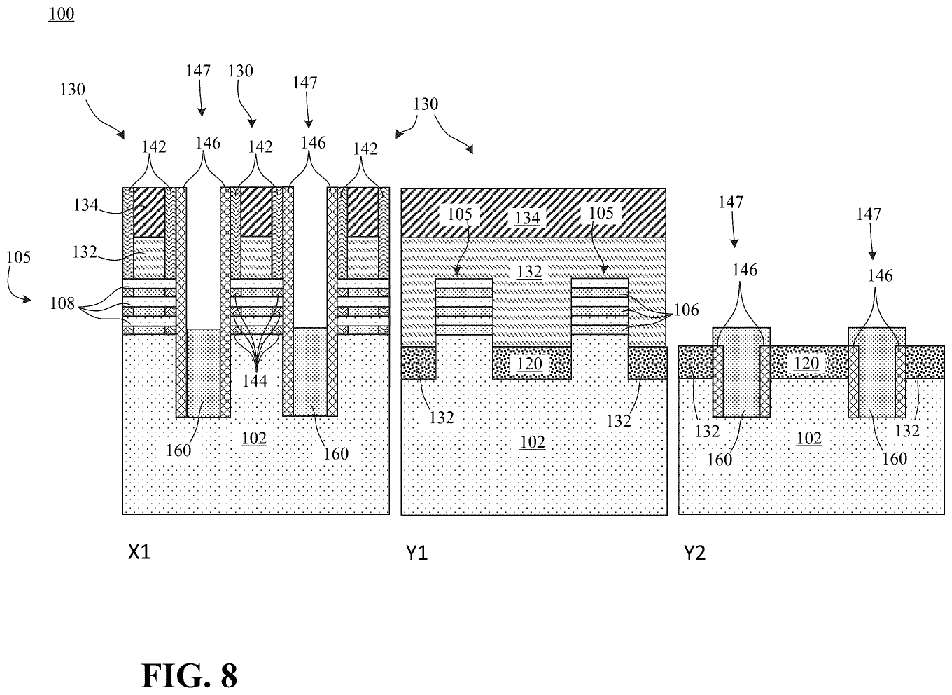

FIG. 8 depicts cross-sectional views of the semiconductor IC device 100 after fabrication operations, in accordance with embodiments of the present disclosure. In the depicted fabrication stages, a backside contact placeholder 160 is formed upon the channel edge liner(s) 146 within each backside contact placeholder trench 147.

The backside contact placeholders 160 may be further formed by epitaxially growing an epitaxial material from exposed substrate structure 102 surface(s) within the backside contact placeholder trenches 147. For example, backside contact placeholders 160 may be epitaxially grown from the well surface of the backside contact placeholder trench 147 that is formed by the substrate structure 102 and may be further formed to directly couple against the channel edge liners 146.

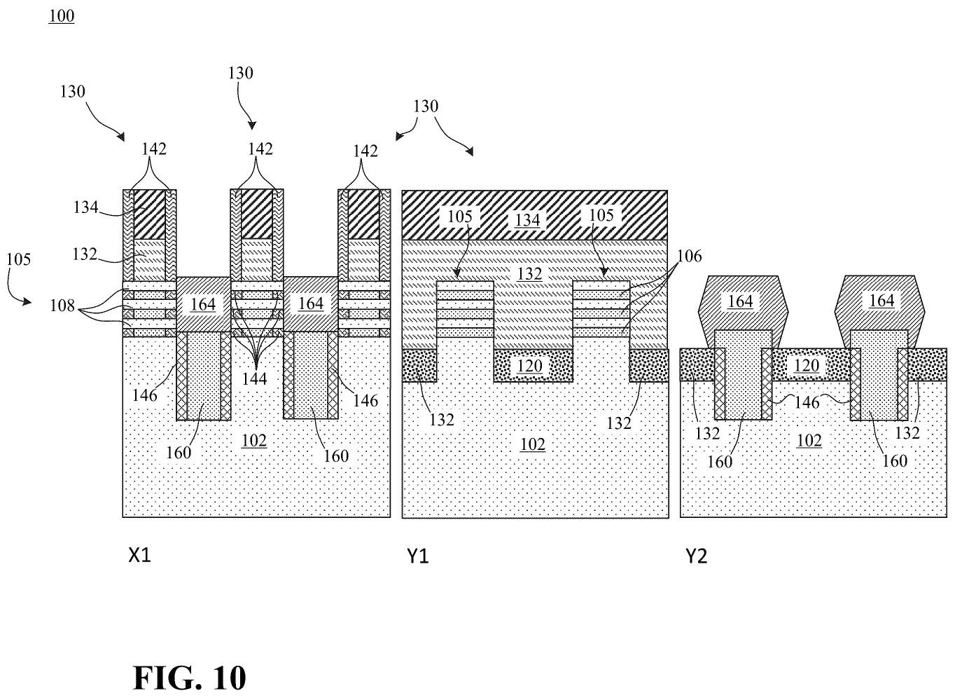

In an example, the epitaxial material of the one or more backside contact placeholders 160 may be chosen to be etch selective to the material of the S/D region(s) 164 (depicted in FIG. 10), the material of the upper substrate structure 102, the material of the channel edge liners 146, or the like.

In an example, as depicted, a barrier layer (not shown) may be formed upon the backside contact placeholder 160 within the backside contact placeholder trenches 147. The barrier layer may be utilized to help protect or mask the associated backside contact placeholder 160 during the etching process(es). The barrier layer(s) may be epitaxially grown from the associated backside contact placeholder 160. The one or more backside contact placeholders 160 may be SiGe and the barrier layer(s) may be Si. For clarity, the top surface of the backside contact placeholder 160 or barrier layer thereupon may be below the bottom surface of the bottommost active nanolayers 108.

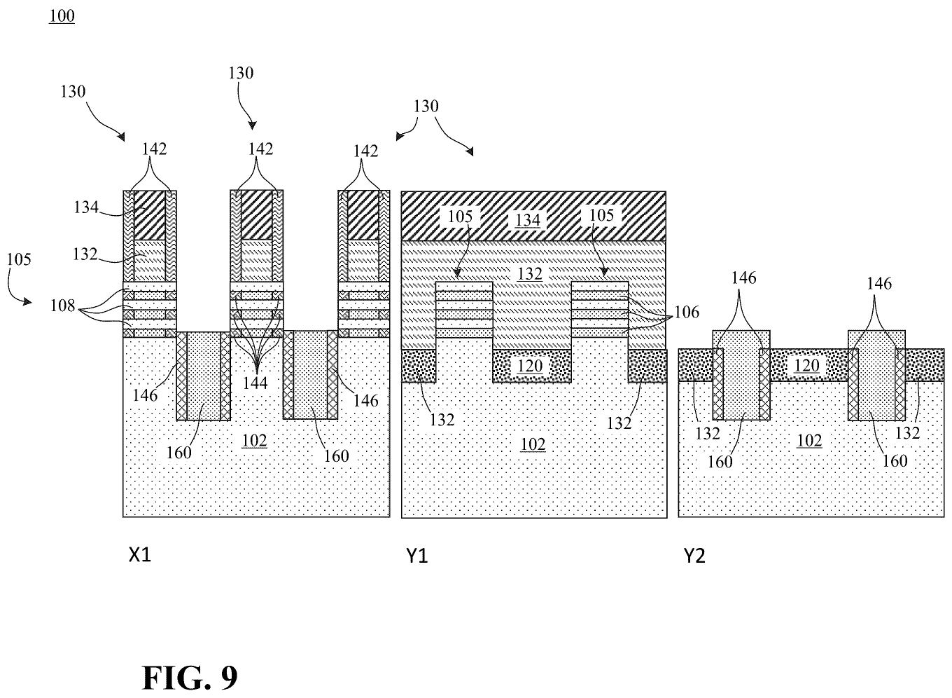

FIG. 9 depicts cross-sectional views of the semiconductor IC device 100 after fabrication operations, in accordance with embodiments of the present disclosure. In the depicted fabrication stages, the channel edge liner(s) 146 may be recessed.

The channel edge liner(s) 146 may be recessed by an etchant that removes the material of the channel edge liners 146 selective to the materials of the gate spacers 142, inner spacers 144, active nanolayers 108, and backside contact placeholders 160, etc. The etch may utilize the top surface of the backside contact placeholders 160 as an etch stop. Therefore, the top surface of the channel edge liner(s) 146 may be substantially coplanar with the backside contact placeholders 160. The top surface of the channel edge liner(s) 146 may be below the bottom active nanolayer 108 to allow for the S/D region 164 (depicted in FIG. 10) to be directly coupled thereto.

FIG. 10 depicts cross-sectional views of the semiconductor IC device 100 after fabrication operations, in accordance with embodiments of the present disclosure. In the depicted fabrication stages, a respective source/drain (S/D) region 164 is formed upon each backside contact placeholder 160.

The respective S/D regions 164 may be formed upon a particular backside contact placeholder 160 or barrier layer (if present). The S/D regions 164 may be formed in a sequential process so that, for example, p-doped S/D regions 164 may be formed in a first formation sequence and then n-doped S/D regions 164 may be formed in a second formation sequence, or vice versa.

Each S/D region 164 may form either a source or a drain, respectively, of a respective transistor and is connected to respective end surfaces of the active nanolayers 108 of one or more nanolayer stacks. Each S/D region 164 is composed of a semiconductor material and a dopant. As used herein, a “source/drain” region can be a source region or a drain region depending on subsequent wiring and application of voltages during operation of the applicable transistor.

The semiconductor material that provides each of the S/D regions 164 may be composed of one of the semiconductor materials mentioned above for the semiconductor structure. For example, the semiconductor material that provides the S/D region 164 can be compositionally the same, or compositionally different from each active nanolayer 108. The dopant that is present in the S/D regions 164 can be either a p-type dopant or an n-type dopant. The term “p-type” refers to the addition of impurities to an intrinsic semiconductor that creates deficiencies of valence electrons. “n-type” refers to the addition of impurities that contributes free electrons to an intrinsic semiconductor. When the semiconductor material is doped with a p-type dopant, the resulting S/D regions 164 are referred to herein as being p-doped and when the semiconductor material is doped with a n-type dopant, the resulting S/D regions 164 are referred to herein as being n-doped.

The S/D regions 164 may be epitaxially grown or formed. In some examples, the S/D regions 164 are formed by in-situ doped epitaxial growth. The use of an in-situ doping process is merely an example. For instance, one may instead employ an ex-situ process to introduce dopants into the S/D regions 164. Other doping techniques can be used to incorporate dopants in the S/D regions 164.

In some examples, the epitaxial growth that forms the S/D region 164 occurs or is promoted from the upper surface of backside contact placeholders 160 (or barrier layer thereupon), from the exposed sidewalls of the active nanolayers 108, or the like, while epitaxial growth may be limited or does not occur from neighboring STI regions 120.

FIG. 11 depicts cross-sectional views of the semiconductor IC device 100 after fabrication operations, in accordance with embodiments of the present disclosure. In the depicted fabrication stages, frontside ILD 176 may be formed, sacrificial gate structures 130 (shown in FIG. 10) may be removed, and replacement gate structures 170 may be formed.

The ILD 176 may be formed by depositing a blanket dielectric material over the S/D region(s) 164, over the STI regions 120, over the sacrificial gate structures 130, over the gate spacers 142, and the like. The ILD 176 can be composed any suitable dielectric material, such as, for example, porous silicates, carbon doped oxides, silicon dioxides, silicon nitrides, silicon oxynitrides, or other dielectric materials. A planarization process, such as a CMP, may be performed to remove excess ILD 176 material and to remove the sacrificial gate caps 134 of the sacrificial gate structures 130, thereby exposing the sacrificial gate 132 thereunder.

The sacrificial gate structures 130 may be removed and replacement gate structures 170 may be formed in place thereof. The sacrificial gate structures 130 may be removed by initially removing the sacrificial gate 132 and sacrificial gate oxide by a removal technique, such as one or more series of etches. For example, such removal may be accomplished by a wet chemical etching process in which one or more chemical etchants are used to remove the sacrificial gate 132 and sacrificial gate oxide of the sacrificial gate structures 130 selective to the active nanolayers 108, inner spacers 144, gate spacers 142, STI regions 120, or the like.

Next, or simultaneously, the active nanolayers 108 may be released by removing the sacrificial nanolayers 106 within the nanolayer stacks. The sacrificial nanolayers 106 may be removed by a removal technique, such as one or more series of etches. After the removal of sacrificial nanolayers, void spaces may be formed above and/or below the active nanolayers 108.

The replacement gate structure 170 may be formed in place of the removed sacrificial gate structures 130 around the released active nanolayers 108, upon STI regions 120, upon the substrate structure 102, etc. The replacement gate structure(s) 170 may be formed by forming an interfacial layer on the gate spacers 142, on the active nanolayers 108, on the substrate structure 102, on the inner spacers 144, etc. that are interior to and/or upon the respective surfaces interior to the opening created by the removal of the sacrificial gate structure 130 and the releasing of the active nanolayers 108.

The replacement gate structure(s) 170 may be further formed by depositing a high-k layer to cover the exposed surfaces of the interfacial layer. A high-K material is a material with a higher dielectric constant than that of SiO₂. The high-K layer can include a single layer or multiple layers, such as metal layer, liner layer, wetting layer, and adhesion layer. The replacement gate structure(s) 170 may be further formed by depositing a work function (WF) gate upon the high-K layer. The WF gate can be comprised of a conductor or metal. In general, the WF gate sets the threshold voltage (Vt) of the device. The high-K layer may separate the WF gate from the nanolayer channel (i.e., active nanolayer 108). Other metals that may be desired to further fine tune the effective work function (eWF) and/or to achieve a desired resistance value associated with current flow through the gate in the direction parallel to the plane of the active nanolayers 108.

The replacement gate structure(s) 170 may be further formed by depositing a conductive gate 172. In an example, when none of the previous replacement gate material(s) are utilized in the replacement gate structures, the conductive gate 172 may be formed upon the same or similar surfaces as those upon which the interfacial layer, described above, may be formed. In other examples, when one or more of the interfacial layer, the high-k layer, the WF gate, or the like, are or are not utilized in the replacement gate structures 170, the conductive gate 172 may be formed upon the most recent structural formation thereof.

The conductive gate 172 can be comprised of a conductor material and/or metal, such as but not limited to, e.g., tungsten, aluminum, ruthenium, rhodium, cobalt, copper, tantalum, titanium, carbon nanowire materials including graphene, or the like. After the replacement gate structure 170 formation, the top surface of the semiconductor IC device 100 may be planarized by a planarization technique such as a CMP, mechanical grinding process, or the like.

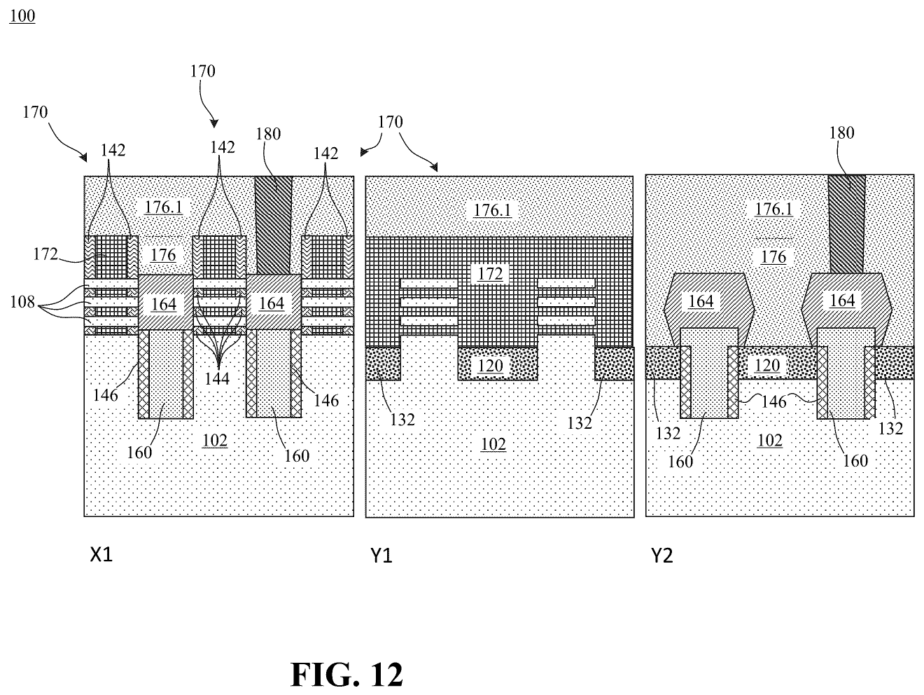

FIG. 12 depicts cross-sectional views of the semiconductor IC device 100 after fabrication operations, in accordance with embodiments of the present disclosure. In the depicted fabrication stages, frontside contact ILD 176.1 may be formed and frontside contacts 180 may be formed.

The frontside contact ILD 176.1 may be formed upon respective top surfaces of replacement gate structure(s) 170, ILD 176, and gate spacers 142. The frontside contact ILD 176.1 may be formed by depositing a dielectric material, such as, for example, porous silicates, carbon doped oxides, silicon dioxides, silicon nitrides, silicon oxynitrides, or other dielectric materials. The material of the frontside contact ILD 176.1 may be the same as the material of the ILD 176, as depicted. Alternatively, the frontside contact ILD 176.1 may be a relatively different dielectric material.

The frontside contacts 180 may be formed by patterning respective frontside contact openings within the ILD 176, the frontside contact ILD 176.1, respectively, from the frontside (i.e., from above the semiconductor IC device 100, as depicted, downward to respective structures thereof). The frontside contacts 180 may be in direct or indirect physical and electrical contact with respective material(s) of one or more regions of the semiconductor IC device 100.

The frontside contact(s) 180 may be formed by depositing conductive material such as metal into the respective frontside contact opening(s). In an example, frontside contact(s) 180 may be formed by depositing a liner, such as Ni, NiPt or Ti, etc. into the contact opening(s), depositing an adhesion liner, such as TiN, TaN, etc. upon the liner, and by depositing a conductive fill, such as Al, Ru, W, Co, Cu, etc. upon the metal adhesion liner. Subsequently, a planarization process, such as a CMP process or a mechanical grinding process, may remove excess portions of the liner, the metal adhesion liner, and the conductive fill. In embodiments, the frontside contact(s) 180 are fabricated in middle-of-line (MOL) fabrication operations and may be illustrations of MOL frontside contacts.

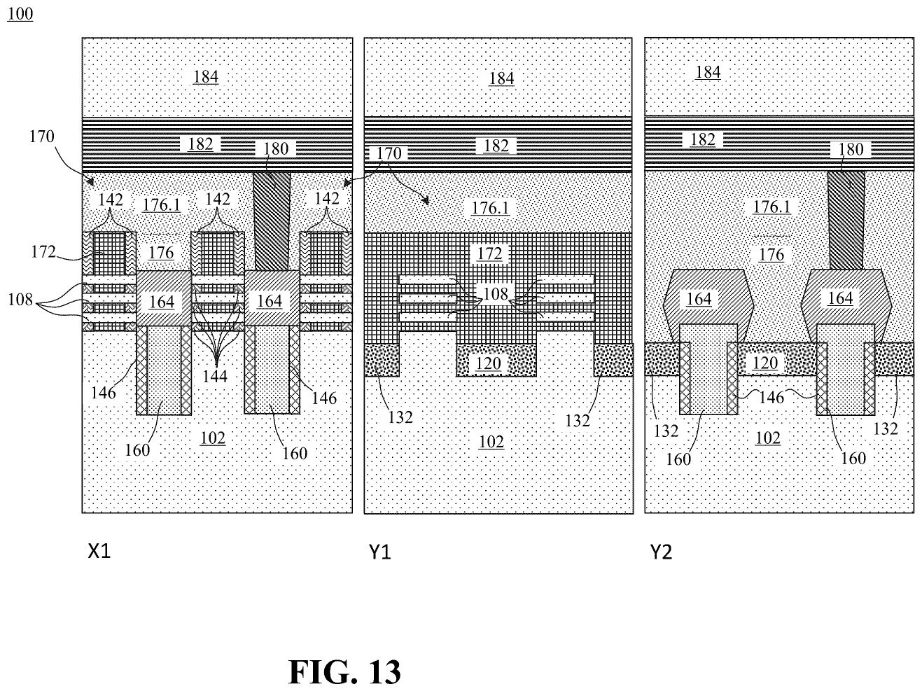

FIG. 13 depicts cross-sectional views of the semiconductor IC device 100 after fabrication operations, in accordance with embodiments of the present disclosure. In the depicted fabrication stages, a frontside back end of line (BEOL) network 182 may be formed and a carrier wafer 184 may be bonded thereto.

In the semiconductor IC device fabrication industry, there are three sections referred to in a build: front-end-of-line (FEOL), BEOL, and the section that connects those two together, the MOL. The FEOL is made up of devices, e.g., transistors, the BEOL is made up of interconnects and wiring, and the MOL includes interconnects between the FEOL and BEOL and material to prevent the diffusion of BEOL conductive material(s) to the FEOL devices.

The BEOL section is the portion of IC fabrication where the individual devices (e.g., transistors, capacitors, resistors, etc.) become interconnected with wiring on the semiconductor IC device, e.g., the metallization layer or layers of a wafer. The BEOL section includes contacts, insulating layers (dielectrics), metal levels, and bonding sites for chip-to-package connections. In the BEOL section, part of the fabrication stage contacts (pads), interconnect wires, vias and dielectric structures are formed. For modern IC processes, more than one metal layers may be added in the BEOL section.

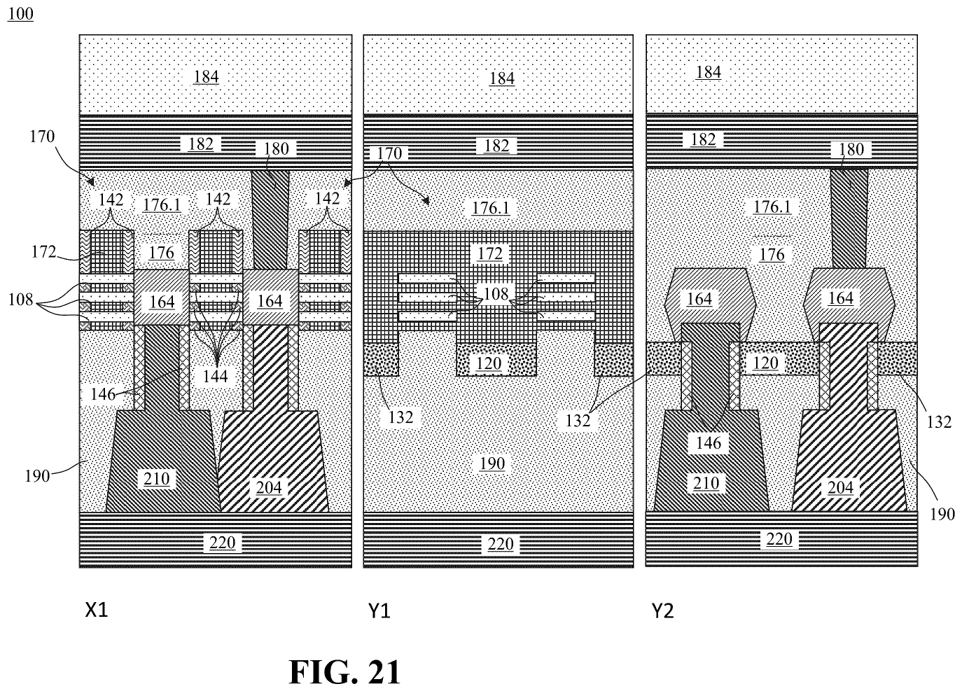

In the present example, there are multiple BEOL levels each on opposites sides of the semiconductor IC device 100. First, a frontside BEOL network 182 is formed on the frontside of the semiconductor device 100. Subsequently, a backside BEOL network 220, as depicted in FIG. 21, is formed.

In the depicted example, the frontside BEOL network 182 is formed over the frontside contact ILD 176.1 and upon the frontside contacts 180. Respective wires within the frontside BEOL network 182 may be electrically connected to the one or more S/D regions 164, to the one or more replacement gate structure(s) 170, or the like, by a respective frontside contact(s) 180. For example, respective wire(s) within the frontside BEOL network 182 may be electrically connected to appropriate S/D regions 164 by a frontside contact 180, another and different group of respective wire(s) within the frontside BEOL network 182 may be electrically connected to appropriate replacement gate structures 170, etc.

The frontside BEOL network 182 can include one or more interconnect dielectric material layers (including one of the dielectric materials mentioned above for the frontside ILD 176) and contains conductive wires (the conductive wires can be composed of any electrically conductive material, metal, electrically conductive metal alloy, or the like) embedded therein. In some embodiments, the frontside conductive wires within the frontside BEOL network 182 are composed of Cu. The frontside BEOL network 182 can include “x” numbers of frontside metal levels, wherein “x” is an integer starting from 1. The frontside BEOL network 182 may further contain conductive pads that are connected to one or more of the conductive wires and may be used to connect the semiconductor IC device 100 to an external and/or higher-level structure, such as a chip carrier, motherboard, or the like.

The illustrated semiconductor IC device 100 may be further fabricated by bonding carrier wafer 184 to the frontside BEOL network 182. The carrier wafer 184 can include one of the semiconductor materials mentioned above for the semiconductor structure and the carrier wafer 184 may be attached to the semiconductor IC device 100 by a wafer-to-wafer bonding technique.

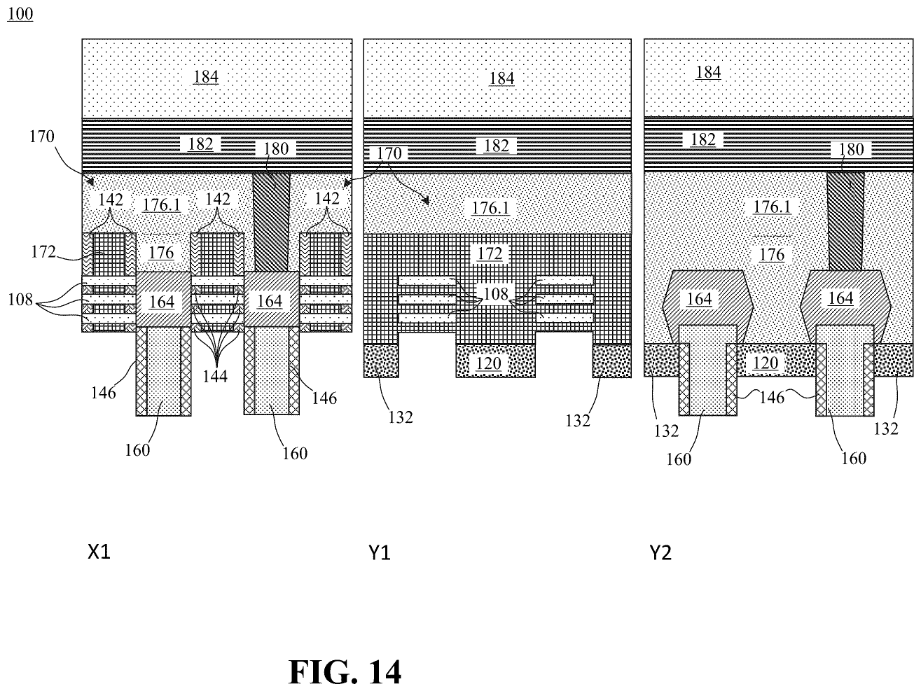

FIG. 14 depicts cross-sectional views of the semiconductor IC device 100 after fabrication operations, in accordance with embodiments of the present disclosure. In the depicted fabrication stages, the substrate structure 102 may be removed.

The substrate structure 102 may be recessed by flipping the semiconductor IC device 100 and removing the substrate structure 102 by an appropriate substrative removal technique, such as an etch. The etch may be timed or otherwise controlled to remove the material of substrate structure 102 selective to the STI regions 120, to the backside contact placeholders 160, to the channel edge liners 146, to the replacement gate structures 170, to the inner spacers 144, or the like.

In some cases, an imperfect removal of substrate structure 102 may occur in which some substrate structure 102 material (not shown) may undesirably retained between backside contact placeholders 160. This residual substrate structure 102 material may traditionally provide a path for leakage current between the S/D regions 164. As such, according to embodiments of the disclosure, the backside contact plug 204, depicted in FIG. 18, may advantageously provide electrical isolation between the S/D regions 164, even if residual substrate structure 102 material is located between the backside contact placeholders 160.

FIG. 15 depicts cross-sectional views of the semiconductor IC device 100 after fabrication operations, in accordance with embodiments of the present disclosure. In the depicted fabrication stages, a backside ILD 190 may be formed.

The backside ILD 190 may be formed upon the backside of the semiconductor IC device 100. The backside ILD 190 may be formed by depositing a dielectric material, such as, for example, porous silicates, carbon doped oxides, silicon dioxides, silicon nitrides, silicon oxynitrides, or other dielectric materials. Any appropriate deposition technique for forming the backside ILD 190 can be utilized. The backside ILD 190 can be formed using, for example, CVD, PECVD, ALD, flowable CVD, spin-on dielectrics, or PVD.

In an example, as depicted, the material of the backside ILD 190 may be the same material as the frontside ILD 176. In alternative examples, the material of the backside ILD 190 may be chosen to achieve a predetermined electrical isolation metric that the dielectric material of frontside ILD 176 could not achieve, if utilized. For example, frontside ILD 176 may be silicon dioxide and the backside ILD 190 may be a low-K dielectric material.

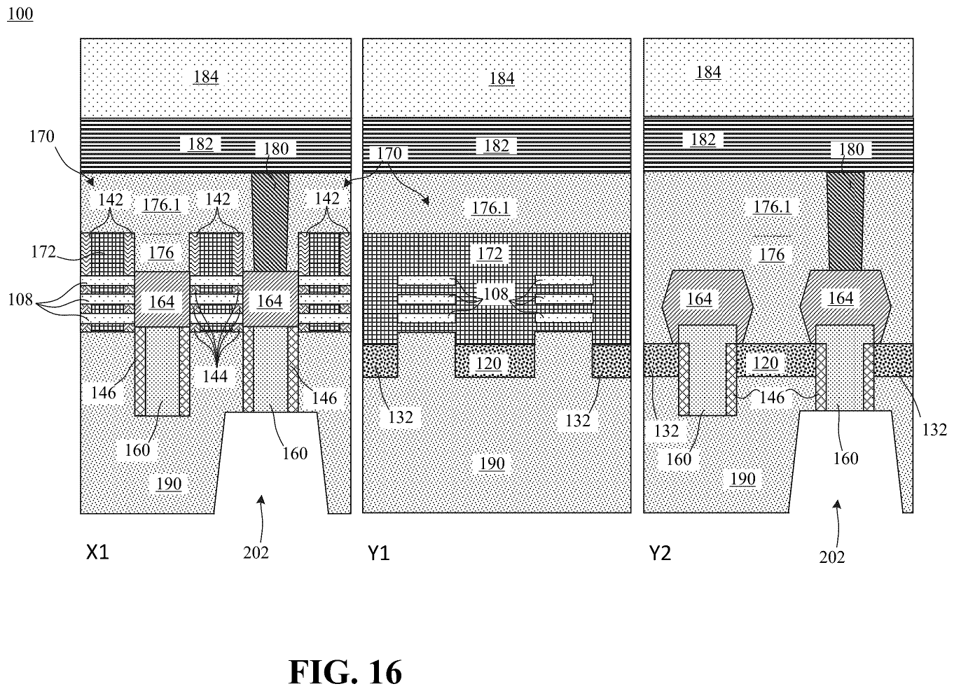

FIG. 16 depicts cross-sectional views of semiconductor IC device 100 shown after illustrative fabrication operation(s), in accordance with one or more embodiments. In the depicted fabrication stage, backside contact plug openings 202 may be established.

The backside contact plug openings 202 may be formed by lithography and etch process(es). In such process(es), a mask (not shown) may be applied to the backside of the semiconductor IC device 100 and patterned. Openings in the patterned mask may sequentially expose the portion(s) of the underlying backside ILD 190 portions that are to be removed while other protected portions of semiconductor IC device 100 may be protected and retained. The backside contact plug openings 202 may be located in each and every location inline with a backside contact placeholder 160 that is associated with a respective S/D region 164 to which a frontside contact 180 is connected. A respective backside contact plug opening 202 may be formed to expose an associated backside contact placeholder 160 there above (e.g., each backside contact placeholder 160 that is below a S/D region 164 that is connected to the frontside BEOL network 182). The backside contact plug opening 202 may have a horizontal dimension greater than a similar horizontal dimension of the associated backside contact placeholder 160 there above, as depicted.

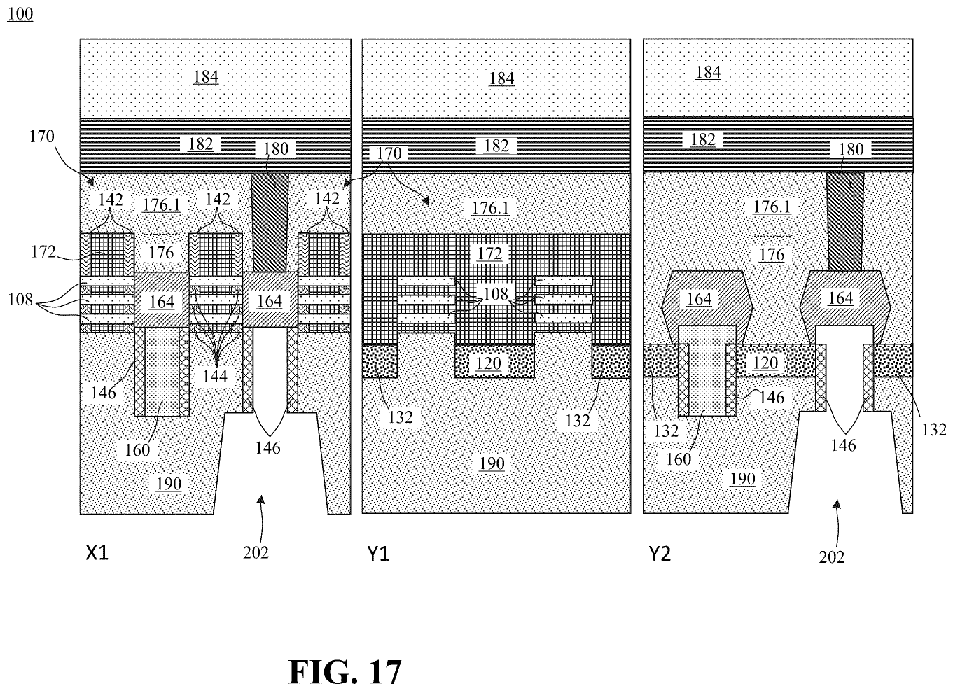

FIG. 17 depicts cross-sectional views of semiconductor IC device 100 shown after illustrative fabrication operation(s), in accordance with one or more embodiments. In the depicted fabrication stage, each contact placeholder 160 exposed by the respective backside contact plug opening 202 may be removed.

The backside contact placeholders 160 that are exposed by respective backside contact plug opening 202 may be removed by a substrative removal technique, such as an etch. In one example, the applicable contact placeholders 160 and barrier layer (if present) associated therewith may be removed. In another example, the applicable contact placeholders 160 is removed using the barrier layer as an etch stop to protect the S/D region 164 there above. In this example, the barrier layer may be retained and the S/D regions 164 are not exposed and/or gouged.

In some examples, the exposed S/D region(s) 164 may be exposed by the removal of the barrier layer and at least partially gouged, or in other words, a lower portion of the exposed S/D region 164 is removed while an upper portion of the exposed S/D region(s) 164 is retained. The lower portion of the S/D region(s) 164 may be removed by a subtractive removal technique, such as an etch. A well surface of the gouge within the S/D region(s) 164 may be below the bottommost active semiconductor nanolayer 108.

FIG. 18 depicts cross-sectional views of semiconductor IC device 100 shown after illustrative fabrication operation(s), in accordance with one or more embodiments. In the depicted fabrication stage, a respective backside contact plug 204 may be formed within a backside contact plug opening 202.

The backside contact plugs 204 may be formed by depositing a dielectric layer over the backside of the semiconductor IC device 100 and within the backside contact plug openings 202. The backside contact plug 204 can be any suitable dielectric material, such as, for example, porous silicates, carbon doped oxides, silicon dioxides, silicon nitrides, silicon oxynitrides, or other dielectric materials. Subsequently, a planarization process, such as a CMP, may be performed to remove excess backside contact plug 204 material and to expose the backside ILD 190. As a result, the respective bottom surfaces of backside contact plugs 204 and backside ILD 190 may be substantially horizontal and/or substantially coplanar.

For clarity, the material of the backside contact plugs 204 may be a relatively different material compared to backside ILD 190, as depicted. This may be beneficial, for example, in situations where a particular backside contact plug 204 is between otherwise adjacent backside contact and relatively more robust (compared to that in which the material of backside ILD 190 provides) electrical isolation, barrier protection, or the like, between the adjacent backside contact.

For clarity, the backside contact plug 204 may directly contact the respective portions of the ILD 190, the channel edge liners 146, and the S/D region 164.

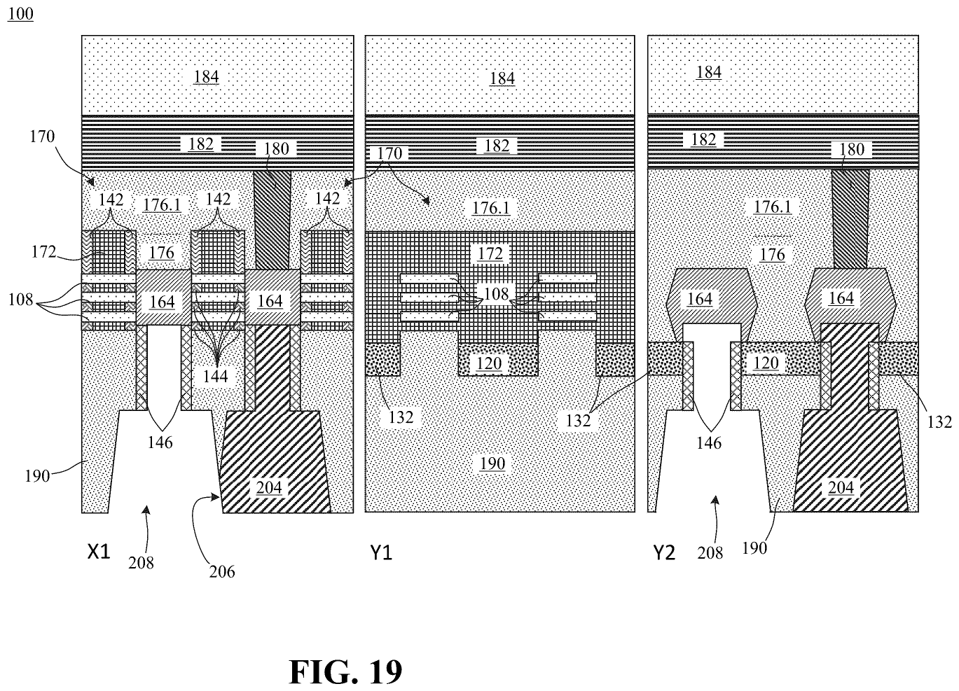

FIG. 19 depicts cross-sectional views of semiconductor IC device 100 shown after illustrative fabrication operation(s), in accordance with one or more embodiments. In the depicted fabrication stage, backside contact openings 208 may be established and expose a respective backside contact placeholder 160 and each exposed contact placeholder 160 by the respective backside contact openings 208 may be removed.

The backside contact openings 208 may be formed by lithography and etch process(es). In such process(es), a mask (not shown) may be applied to the backside of the semiconductor IC device 100 and patterned. Openings in the patterned mask may sequentially expose the portion(s) of the underlying backside ILD 190 that are to be removed while other protected portions of semiconductor IC device 100 may be protected and retained. The backside contact opening 208 may be located inline with a particular backside contact placeholder 160 that is associated with a respective S/D region 164 in which a frontside contact 180 is not connected. A backside contact opening 208 may be formed to expose the associated backside contact placeholder 160 there above and formed to expose the associated channel edge liners 146 (e.g., the channel edge liners 146 on the sidewall(s) of the presently removed backside contact placeholder 160). Further, the backside contact opening 208 may be formed to expose and cut into a portion of an adjacent backside contact plug 204 so as to expose a sidewall 206 of the adjacent backside contact plug 204. The backside contact openings 208 may have a horizontal dimension greater than a similar horizontal dimension of the associated backside contact placeholder 160 there above, as depicted.

Further, in the depicted fabrication stage, each contact placeholder 160 that is exposed by a respective backside contact opening 208 may be removed. The backside contact placeholders 160 that are exposed by respective backside contact openings 208 may be removed by a substrative removal technique, such as an etch. In one example, the applicable contact placeholders 160 and barrier layer (if present) associated therewith may be removed. In another example, the applicable contact placeholders 160 is removed using the barrier layer as an etch stop to protect the S/D region 164 there above. In this example, the barrier layer may be retained and the S/D regions 164 are not exposed and/or gouged.

In some examples, the exposed S/D region(s) 164 may be exposed by the removal of the barrier layer and at least partially gouged, or in other words, a lower portion of the exposed S/D region 164 is removed while an upper portion of the exposed S/D region(s) 164 is retained. The lower portion of the S/D region(s) 164 may be removed, and thereby gouged, by a subtractive removal technique, such as an etch. A well surface of the gouge within the S/D region(s) 164 may be below the bottommost active semiconductor nanolayer 108.

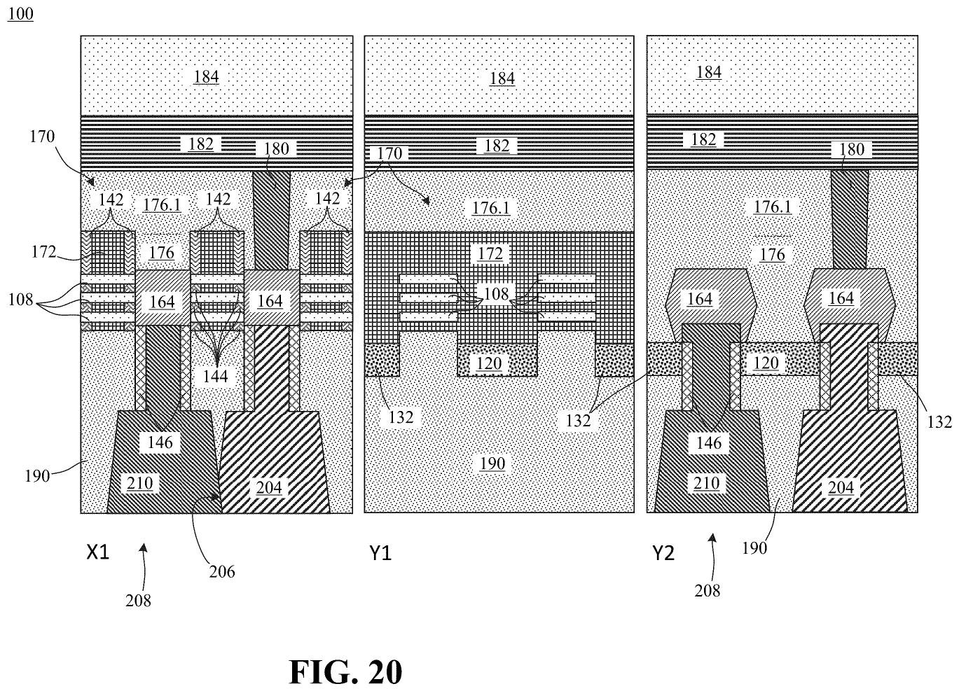

FIG. 20 depicts cross-sectional views of semiconductor IC device 100 shown after illustrative fabrication operation(s), in accordance with one or more embodiments. In the depicted fabrication stage, a backside contact 210 may be formed within a respective backside contact opening 208.

A respective backside contact 210 may be formed within a respective backside contact opening 208 against the associated S/D region 164 by depositing conductive material, such as metal, therein. In an example, multiple backside contacts 210 may be simultaneously formed by depositing a liner, such as Ni, NiPt or Ti, etc. onto the backside of semiconductor IC device 100 and into the backside contact openings 208, depositing an adhesion liner, such as TIN, TaN, etc. upon the liner, and by depositing a conductive fill, such as Al, Ru, W, Co, Cu, etc. upon the adhesion liner.

Subsequently, a planarization process, such as a CMP, may expose a bottom surface of the backside ILD 190 and a bottom surface of the backside contact plugs 204. As a result, the respective bottom surfaces of backside contacts 210, backside contact plugs 204, and backside ILD 190 may be substantially horizontal and/or substantially coplanar.

For clarity, in some examples, all backside contact placeholders 160 within the semiconductor IC device 100 may be removed by the present fabrication stage. One group of backside contact placeholders 160 (i.e., those backside contact placeholders 160 that were contacted against a S/D region 164 that is connected to a frontside contact 180) are removed during the formation of the backside contact plugs 204. The only other group of backside contact placeholders 160 (i.e., those backside contact placeholders 160 that are removed so as to form the backside contacts 210 in place thereof) are removed during the formation of the backside contacts 210.

FIG. 21 depicts cross-sectional views of semiconductor IC device 100 shown after illustrative fabrication operation(s), in accordance with one or more embodiments. In the depicted fabrication stage, a backside BEOL network 220 may be formed.

The backside BEOL network 220, such as a backside power distribution network (BSPDN) may be formed upon the backside contacts 210, upon the backside ILD 190, and upon the backside contact plugs 204. The backside BEOL network 220 may include signal wires for signal routing and power wires for providing power potential (e.g., VDD, VSS, etc.). The backside BEOL network 220 may allow for the distribution of power wires and signal wires between both the frontside and backside of the semiconductor IC device. The backside BEOL network 220 may further allow for the full or partial decoupling of signal routing and/or power routing and/or allows for dividing or splitting power wires and/or signal wires between both the frontside and backside of the semiconductor IC device. By incorporating the backside BEOL network 220, wire and contact routing congestion may be reduced, which may lead to further semiconductor IC device 100 scaling. For example, semiconductor IC devices that incorporate a backside BEOL network can result in a 30% area reduction and improved current-resistance (IR) drop compared to typical semiconductor IC devices that include solely a frontside BEOL network.

The backside BEOL network 220 may be electrically connected to the one or more S/D regions 164 by way of a particular backside contact 210. For example, a first backside wire within the backside BEOL network 220 may be electrically connected the backside contact 210, or the like.

The backside BEOL network 220 can include one or more interconnect dielectric material layers and contains backside conductive wires and/or interconnects, such as VIAs, embedded therein. In some embodiments, the backside wires within the backside BEOL network 220 are composed of Cu. The backside BEOL network 220 can include “x” numbers of backside metal levels, wherein “x” is an integer starting from 1. If not included in frontside BEOL network 182, backside BEOL network 220 may further contain conductive pads that are connected to one or more of the backside metal wires and may be used to connect the semiconductor IC device 100 to the external and/or higher-level structure.

In an example, signal routing and power routing is effectively split between the frontside BEOL network 182 and the backside BEOL network 220. For example, at least 90% of the frontside metal wires (e.g., furthest from the depicted transistors) are signal routing metal wires and the remainder frontside metal wires which are usually present in metal levels closest to the transistors, can be used as power routing wires. Further in this example, at least 90% of the backside metal wires that are in metal levels closest to the backside contacts are power routing metal wires. Power routing wires may be less dense than signal routing wires. A signal routing wire is defined herein as a conductive feature, such as a wire, interconnect, or the like, that is configured to carry or have a functional or logical potential or signal that is to change or is otherwise dynamic over time. A power routing wire is defined herein as a conductive feature, such as a wire, trace, plane, or the like, that is configured to electrically carry power potential. For example, a power routing wire carries or otherwise has a functional power potential, such as VDD, VSS, or the like.

Semiconductor IC device 100 may be an integrated circuit (IC) chip. IC chips can be distributed by the fabricator in raw wafer form (that is, as a single wafer that has multiple unpackaged chips), as a bare die, or in a packaged form. In the latter case, the IC chip may mount in a single chip package (such as a plastic carrier, with leads that are affixed to a motherboard or other higher-level carrier) or in a multichip package (such as a ceramic carrier that has either or both surface interconnections or buried interconnections). In any case, the IC chip may be integrated with other chips, discrete circuit elements, and/or other signal processing devices as part of either (a) an intermediate product, such as a motherboard, or (b) an end product. The end product can be any product that includes the IC chip, ranging from toys and other low-end applications to advanced computer products having a display, a keyboard or other input device, and a central processor.

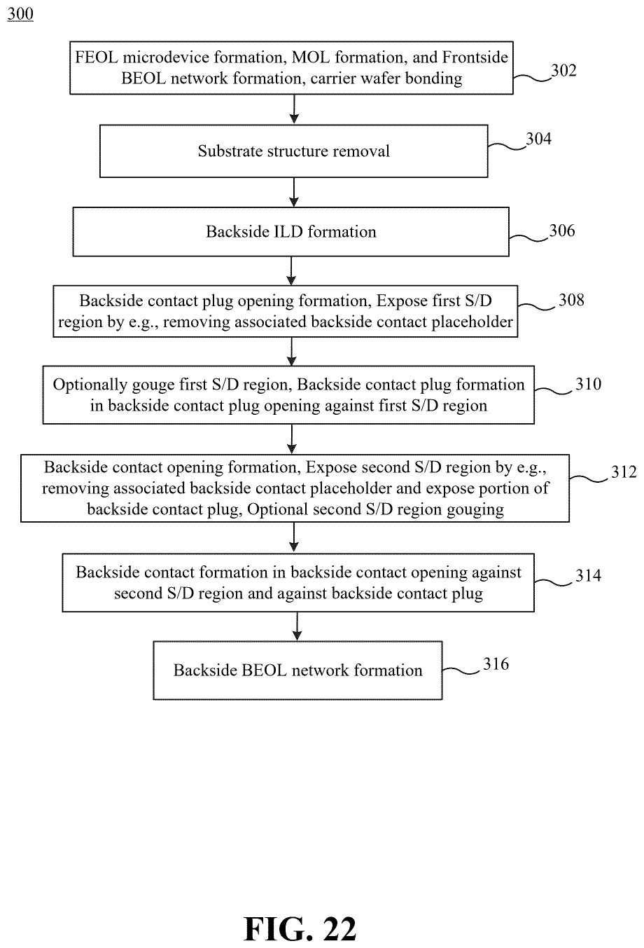

FIG. 22 depicts a flow diagram illustrating a method 300 to fabricate a semiconductor IC device, such as semiconductor IC device 100. The depicted fabrication operations of method 300 are illustratively depicted and described above with reference to one or more of FIG. 2B through FIG. 21 of the drawings, which describe the fabrication of semiconductor IC device 100, though the fabrication operations described in method 300 may be used to fabricate other types of semiconductor IC devices. The method 300 depicted herein is illustrative. There can be many variations to the diagram or operations described therein without departing from the spirit of the embodiments. For instance, the operations can be performed in a differing order, or operations can be added, deleted, or modified.

At block 302, method 300 may begin with forming one or more front end of line (FEOL) microdevices, such as transistors, with forming middle of line (MOL) structures, such as frontside contact(s), with forming a frontside back end of line (BEOL) network, and with attaching a carrier wafer thereto. For example, one or more transistors are formed within the semiconductor IC device 100. Further, for example, one or more frontside contacts 180 are formed that may contact components or regions (such as S/D regions 164, replacement gate structures 170, etc.) of such transistors, the frontside BEOL network 182 is formed upon the one or more frontside contacts 180, and a carrier wafer 184 is bonded to the frontside BEOL network 182.

At block 304, the semiconductor IC device may be flipped (not depicted in the drawings), and a substrate structure associated with the FEOL microdevices may be partially removed. For example, the substrate structure 102 may be removed. At block 306, method 300 may continue with forming a backside ILD. For example, the backside ILD 190 may be deposited upon the backside placeholders 160, upon channel edge liners 146, upon the STI regions 120, or the like.

At block 308, method 300 may continue with forming a backside contact plug opening(s) and exposing the associated S/D region. For example, backside contact plug opening(s) 202 may be formed within the backside ILD 190. The backside contact plug opening 202 may expose an associated backside contact placeholder 160 that is connected to the frontside contact 180. The first S/D region 164 may be exposed by removing this backside contact placeholder 160, etc. by way of the backside contact opening 202.

At block 310, method 300 may continue with optionally gouging the first S/D region and with forming a backside contact plug against the first S/D region. For example, the first S/D region 164 may be gouged and a respective backside contact plug 204 may be formed within the backside contact opening 202 against the first S/D region 164.

At block 312, method 300 may continue with forming a backside contact opening, with removing an associated backside contact placeholder, and with optionally gouging a second S/D region. For example, backside contact opening(s) 208 may be formed within the backside ILD 190. The backside contact opening(s) 208 may expose an associated backside contact placeholder 160. A second S/D region 164 may be exposed by removing the backside contact placeholder 160 by way of the backside contact plug opening 208. The second S/D region 164 may be optionally gouged by way of the backside contact opening 208.

At block 314, method 300 may continue with forming a backside contact in the backside contact opening against the second S/D region. For example, backside contact 210 is formed in the backside contact opening 208 against the second S/D region 164.

At block 316, method 300 may further continue with forming a backside BEOL network over the backside contact(s), over the backside ILD, and/or over the backside contact plug(s). For example, the backside BEOL network 220 may be formed over the backside ILD 190, over the backside contacts 210, and over the backside contact plugs 204.

For clarity, in an embodiment of the present disclosure, method 300 includes forming the backside dielectric plug opening 202 within a backside ILD 190 that exposes a first backside contact placeholder 160, exposing a first source/drain region 164 by removing the first backside contact placeholder 160, and forming a backside dielectric plug 204 within the backside dielectric plug opening 202 against the first source/drain region 164. The method 300 also includes, after forming the backside dielectric plug, forming a backside contact opening 208 within the backside ILD 190 that exposes a second backside contact placeholder 160 and that exposes a portion of the backside dielectric plug 204. The method 300 further includes exposing a second source/drain region 164 by removing the second backside contact placeholder 160 and forming a backside contact 210 within the backside contact opening 208 against the second source/drain region 164 and against the portion of the backside dielectric plug 204.

The backside dielectric plug 204 may replace an associated backside contact placeholder 160 that would otherwise remain underneath the first source/drain region 164. Relative to the backside contact placeholder 160, the backside dielectric plug 204 may reduce parasitic capacitance between the replacement gate structure 170, shown for example in FIG. 21, and the first source/drain region 164 or between the replacement gate structure 170 and the second source/drain region 164. Further, relative to the backside contact placeholder 160, the backside dielectric plug 204 may reduce the capacitance between the first source/drain region 164 and the second source/drain region 164. Even further, relative to the backside contact placeholder 160, the backside dielectric plug 204 may reduce leakage current between the first source/drain region 164 and the second source/drain region 164 through substrate residue (not shown) that may reside due to flawed substrate structure 102 removal during backside processing, shown for example in FIG. 14.

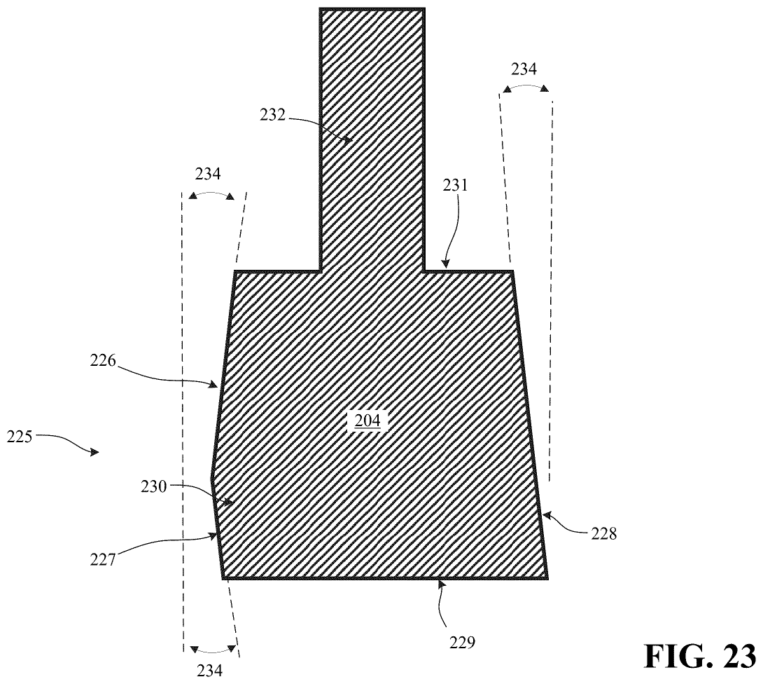

FIG. 23 depicts a cross-section view of backside dielectric plug 204, according to one or more embodiments of the disclosure. The backside dielectric plug 204 may include a lower portion 230 and an upper portion 232. A horizontal width in the depicted cross-section of the lower portion 230 is generally wider than a horizontal width of the upper portion 232. The lower portion 230 may have a top surface 231 and a bottom surface 229. The lower portion 230 may have one or more linear sidewalls 228 and one or more gabled sidewalls 225.

The gabled sidewall 225 may include a flared sidewall 226 and a flared sidewall 227 that is generally oppositely flared or sloped relative to the flared sidewall 226. For example, the flared sidewall 226 may be positively sloped and the flared sidewall 227 may be negatively sloped. In this example, the backside dielectric plug 204 may have substantially parallel sidewalls 227, 228, that may be angled or flared by an angle 234 from vertical. The relatively oppositely flared sidewall 227 may be the portion of the backside dielectric plug 204 that is directly coupled to the backside contact 210, shown for example, in FIG. 21. Such direct contact between the backside dielectric plug 204 and the backside contact 210 generally may reduce a relative horizontal pitch between semiconductor IC device 100 components, which may be beneficial for further semiconductor IC device scaling. The relatively oppositely flared sidewall 227 may be formed by the backside contact opening 208, shown in FIG. 19, cutting or removing a portion of the backside dielectric plug 204.

The flared sidewall 226 may be angled from vertical with an orientation such that the flared sidewall 226 is decreasing in distance away from vertical toward the bottom surface 229 of the backside dielectric plug 204. The flared sidewall 227 may be angled from vertical with an orientation such that the flared sidewall 227 is increasing in distance away from vertical toward the bottom surface 229 of the backside dielectric plug 204.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor integrated circuit (IC) device comprising:
a first source/drain region connected to a second source/drain region by a plurality of active channels;
a backside contact that is directly coupled to the first source/drain region;
a frontside contact that is directly coupled to the second source/drain region; and
a backside dielectric plug that is directly coupled to the second source/drain region and that is directly coupled to the backside contact.

2. The semiconductor IC device of claim 1, wherein a portion of a sidewall of the backside dielectric plug is directly coupled to a portion of a sidewall of the backside contact.

3. The semiconductor IC device of claim 2, further comprising:
a frontside back end of line network that is connected to the frontside contact.

4. The semiconductor IC device of claim 3, further comprising:
a backside back end of line network that is connected to the backside contact and to the backside dielectric plug.

5. The semiconductor IC device of claim 4, further comprising:
a gate that is connected to the plurality of active channels.

6. The semiconductor IC device of claim 5, wherein the plurality of active channels are vertically stacked.

7. The semiconductor IC device of claim 1, further comprising a backside interlayer dielectric (ILD) directly coupled to the backside contact and directly coupled to the backside dielectric plug.

8. The semiconductor IC device of claim 7, wherein the backside dielectric plug comprises a gabled sidewall comprising a first sidewall surface directly coupled to the backside ILD and a second sidewall surface that meets the first sidewall surface and that is directly coupled to the backside contact.

9. The semiconductor IC device of claim 8, wherein the backside dielectric plug is composed of a first dielectric material and the backside ILD is composed of a second dielectric material that is different from the first dielectric material.

10. The semiconductor IC device of claim 9, wherein the backside dielectric plug comprises an upper region with a first horizontal dimension and a lower region with a second horizontal dimension greater than the first horizontal dimension.

11. The semiconductor IC device of claim 10, wherein the backside contact comprises a linear sidewall that is directly coupled to the backside ILD and that is directly coupled to backside dielectric plug.

12. The semiconductor IC device of claim 10, further comprising:
a vertical liner that is directly coupled to the upper region of the backside dielectric plug and that is directly coupled to the backside ILD.

13. A semiconductor integrated circuit (IC) device comprising:
a totality of source/drain regions in the semiconductor IC device, the totality of source/drain regions consisting of first source/drain regions and second source/drain regions;
the first source/drain regions are each directly connected to a respective backside contact; and
the second source/drain regions are each directly coupled to a respective frontside contact and are each directly coupled to a backside dielectric plug.

14. The semiconductor IC device of claim 13, wherein each backside dielectric plug is directly coupled to one or more of the backside contacts.

15. The semiconductor IC device of claim 14, further comprising:
a frontside back end of line network that is connected to each of the respective frontside contacts.

16. The semiconductor IC device of claim 15, further comprising:
a backside back end of line network that is connected to each of the respective backside contacts and that is connected to each of the respective backside dielectric plugs.

17. The semiconductor IC device of claim 16, further comprising a backside interlayer dielectric (ILD) directly coupled to each of the respective backside contacts and directly coupled to each of the respective backside dielectric plugs.

18. The semiconductor IC device of claim 17, wherein each of the respective backside dielectric plugs comprises a gabled sidewall comprising a first sidewall surface directly coupled to the backside ILD and a second sidewall surface that meets the first sidewall surface and that is directly coupled to backside contact.

19. The semiconductor IC device of claim 18, wherein each of the respective backside dielectric plugs are composed of a first dielectric material and the backside ILD is composed of a second dielectric material that is different from the first dielectric material.

20. A semiconductor integrated circuit (IC) device fabrication method comprising:
forming a backside dielectric plug opening within a backside interlayer dielectric that exposes a first backside contact placeholder;
exposing a first source/drain region by removing the first backside contact placeholder;
forming a backside dielectric plug within the backside dielectric plug opening against the first source/drain region;
after forming the backside dielectric plug, forming a backside contact opening within the backside interlayer dielectric that exposes a second backside contact placeholder and that exposes a portion of the backside dielectric plug;
exposing a second source/drain region by removing the second backside contact placeholder; and
forming a backside contact within the backside contact opening against the second source/drain region and against the portion of the backside dielectric plug.
